(19) United States
(12) Patent Application Publication
(10) Pub. No.: US 2024/0200228 A1
(43) Pub. Date: Jun. 20, 2024

(54) Tantalum Nitride Doped With One Or More Metals, A Catalyst, Methods For Water Splitting Using The Catalyst, And Methods To Make Same

(71) Applicants: Global Advanced Metals USA, Inc., Wellesley Hills, MA (US); Shinshu University, Nagano (JP)

(72) Inventors: Kazunari DOMEN, Nagano (JP); Takashi HISATOMI, Nagano (JP); Jiadong XIAO, Nagano (JP); Mary KRAUSE, Phoenixville, PA (US); Aijun YIN, Schwenksville, PA (US); Gordon SMITH, Arlington Heights, IL (US)

(73) Assignees: Global Advanced Metals USA, Inc., Wellesley Hills, MA (US); Shinshu University, Nagano (JP)

(21) Appl. No.: 18/287,303

(22) PCT Filed: May 4, 2022
(86) PCT No.: PCT/US2022/027562

§ 371 Date: Oct. 18, 2023

Related U.S. Application Data
(60) Provisional application No. 63/184,816, filed on May 6, 2021.

(51) Int. Cl. C30B 29/38; B01J 27/24; B01J 35/23; B01J 35/39; B01J 35/45; B01J 35/55; B01J 37/02; B01J 37/16

(52) U.S. Cl. CPC C30B 29/38; B01J 27/24; B01J 35/23; B01J 35/39; B01J 35/45; B01J 35/55; B01J 37/0201; B01J 37/16

(57) ABSTRACT

Single crystalline nanoparticles that are tantalum nitride doped with at least one metal are described. The single crystalline nanoparticles can be doped with two metals such as Zr and Mg. The single crystalline nanoparticles can be Ta₃N₅:Mg+Zr, or Ta₃N₅:Mg, or Ta₃N₅:Zr or any combination thereof. Catalyst containing the single crystalline nanoparticles alone or with one or more co-catalyst are further described along with methods of making the nanoparticles and catalyst. Methods to split water utilizing the catalyst are further described.

This application claims the benefit under 35 U.S.C. § 119(e) of prior U.S. Provisional Patent Application No. 63/184,816, filed May 6, 2021, which is incorporated in its entirety by reference herein.

### BACKGROUND OF THE INVENTION

Water splitting to form hydrogen and oxygen using solar energy in the presence of photocatalysts has been studied as a potential means of clean, large-scale fuel production. Hydrogen fuel production has gained increased attention with the concerns about global warming. Methods such as photocatalytic water splitting are being investigated to produce hydrogen, a clean-burning fuel. Water splitting holds particular promise since it utilizes water, an inexpensive renewable resource. Photocatalytic water splitting has the simplicity of using a catalyst and sunlight to produce hydrogen out of water.

In contrast to the two-step system of photovoltaic production of electricity and subsequent electrolysis of water, photocatalytic water splitting processes are performed by photocatalysts being in direct contact with water. The photocatalysts are either in homogeneous environments with respect to the water (photocatalysts suspended within the water) or are in a heterogeneous phase with respect to the water (photocatalysts bound to a surface in contact with the water). Examples of heterogeneous photocatalytic processes include that described in U.S. Pat. No. 10,744,495 and US2014/0174905. Whether homogeneous or heterogeneous, photocatalytic water splitting is more efficient than the two-step process of water electrolysis.

The prime measure of photocatalyst effectiveness is quantum yield (QY), which is:

QY (%)=(Photochemical reaction rate)/(Photon absorption rate)×100%.

This quantity is a reliable determination of how effective a photocatalyst is. Overall, the best photocatalyst has a high quantum yield and gives a high rate of gas evolution.

For a photocatalytic reaction, the quantum efficiency (QE) for photon-to-hydrogen conversion is the key parameter when evaluating the efficiency of renewable solar energy to hydrogen fuel systems. Almost all the reported photocatalytic water-splitting systems suffer from low QE in the visible-light region (e.g., rarely exceeding 3% at 420 nm), which largely hinders any potential practical applications.

The present invention relates to tantalum nitrides, in particular tantalum nitrides doped with one or more metals, and products containing or made from the tantalum doped with one or more metals, such as, but not limited to, a catalyst.

The present invention also relates to methods utilizing the tantalum doped with one or more metals, such as, but not limited to, methods to obtain hydrogen from solutions (e.g., aqueous solutions such as water) and methods for water splitting using the catalyst. The present invention further relates to methods of making the tantalum nitride doped with one or more metals and the catalyst.

Tantalum nitride (e.g., Ta₃N₅), an n-type semiconductor with a narrow bandgap (2.1 eV) and suitable energetic positions of conduction and valance bands straddling the water redox potentials, is a potential photocatalyst for producing sustainable hydrogen via solar photocatalytic water splitting. Despite a theoretically maximum solar-to-hydrogen (STH) energy conversion efficiency of 15.9%, the STH value achieved so far by overall water splitting (OWS) over Ta₃N₅ was only about 0.014%, and this was done by using nanorods grown on lattice-matched KTaO₃. The apparently imbalanced water oxidation and reduction performance of Ta₃N₅ has long been an obstacle to the realization of OWS for this material. Compared with the water oxidation, photocatalytic water reduction activity of Ta₃N₅ has been always much poorer or even undetectable in some cases, though a variety of modifications (e.g., size minification, heterojunction, and surface modification) were considered and/or attempted but the progress thus far made is viewed as unsatisfactory. Hence, developing efficient strategies to substantially improve the water reduction activity of tantalum nitrides, such as Ta₃N₅ is still needed.

In addition, compositional modification of a photocatalyst material by doping with foreign ions has been considered to a certain degree and this doping has had an effect on photocatalytic performance. For Ta₃N₅, certain aliovalent metal ions, particularly Mg²⁺ (72 pm) and Zr⁴⁺ (72 pm) with similarly large ionic radius to Ta⁵⁺ (64 pm), were introduced into its crystal lattice, and this enhanced performance in photocatalytic/photoelectrochemical water oxidation and splitting to a certain extent. A lower photocurrent onset potential by the design of Mg—Zr co-doped Ta₃N₅ photoanode has been attempted. However, efficient photocatalytic water reduction, conceivably the bottleneck of this material for photocatalytic OWS, has not been well demonstrated by this doping method. On the other hand, impurities, such as MgO and Zr₂ON₂, were formed with Ta₃N₅, going against correctly catching the individual functionality of the dopant on single-phase Ta₃N₅. Variation in the number of different defect species (containing reduced Ta, oxygen impurity (O_{N}), and nitrogen vacancy (V_{N})) arising from aliovalent doping has mainly been considered the reason for the activity enhancement. However, only part of them (mostly ON) have been directly detected. On the contrary, V_{N} in Ta₃N₅ has never been directly captured and the nature of reduced Ta (Ta³⁺ or Ta⁴⁺ or both) was still controversial.

Moreover, the surface property that affects the cocatalyst loading and dispersion was very often ignored. All these have led to a poor mechanistic understanding of the doping-induced activity improvement, hindering further rational design and synthesis of active Ta₃N₅ photocatalysts that can overcome and/or improve the performance as a catalyst.

Accordingly, there is a need in the industry to provide improved nanoparticles and especially improved tantalum nitrides that find use, for instance, as catalyst and for use in methods for water splitting and/or other uses.

### SUMMARY OF THE PRESENT INVENTION

It is therefore a feature of the present invention to provide a novel tantalum nitride.

A further feature is to provide a single-phase tantalum nitride that is doped with one or more metals.

A further feature is a catalyst that is or includes the single-phase tantalum nitride that is doped with one or more metals.

An additional feature of the present invention is to provide a nanoparticle that is a tantalum nitride that is co-doped with one or two or more metals.

Another feature of the present invention is to provide a catalyst, such as for water reduction.

Another feature of the present invention is to provide a water splitting catalyst.

Another feature of the present invention is to provide a method to water split using nanoparticles such as in the form of a catalyst.

Another feature of the present invention is to provide methods of making the novel tantalum nitrides and catalysts.

Additional features and advantages of the present invention will be set forth in part in the description that follows, and in part will be apparent from the description, or may be learned by practice of the present invention. The objectives and other advantages of the present invention will be realized and attained by means of the elements and combinations particularly pointed out in the description and appended claims.

To achieve these and other advantages, and in accordance with the purposes of the present invention, as embodied and broadly described herein, the present invention relates to single crystalline nanoparticles that are tantalum nitride doped with at least one metal. The single crystalline nanoparticles can be a tantalum nitride that is co-doped with two metals. For instance, the two metals can be Zr and Mg. As an option, and preferably, the doped metal(s) reside as a cation(s) in a crystal lattice of the tantalum nitride.

The present invention further relates to single crystalline nanoparticles that are Ta₃N₅:Mg+Zr, or Ta₃N₅:Mg, or Ta₃N₅:Zr or any combination thereof.

The present invention further relates to a catalyst that includes the single crystalline nanoparticles of the present invention alone or optionally along with a co-catalyst(s). The co-catalyst can be distributed or dispersed on or used with the single crystalline nanoparticles. The co-catalyst can be a platinum metal (Pt) that is homogeneously distributed or dispersed on the single crystalline nanoparticles or mixed with the nanoparticles or used in combination with the nanoparticles.

Further, the present invention relates to a method to water split, and method includes the step of utilizing the catalyst (e.g., photocatalyst) in contact with water or other fluid.

The present invention also relates to a method to make the single crystalline nanoparticles of the present invention. The method can include impregnating a NaCl/Ta with MgCl₂ or other first metal salt and ZrOCl₂ or other second metal salt and then conducting nitridation under a flow of gas. The nitriding can be conducted under high temperatures such as, but not limited to, 900 deg C. or higher. The NaCl/Ta can be a NaCl-encapsulated Ta that can be obtained from a sodium/halide flame encapsulation method.

In addition, the present invention relates to a method to make a catalyst with a co-catalyst. The method includes the step of Pt loading of the single crystalline nanoparticles. The Pt loading can include or involve deposition of Pt by an impregnation-reduction method followed by deposition of more Pt by an in-situ photodeposition method. In lieu of Pt or in addition to Pt, other co-catalysts can be utilized, such as, but not limited to, other metals.

It is to be understood that both the foregoing general description and the following detailed description are exemplary and explanatory only and are intended to provide a further explanation of the present invention, as claimed.

### BRIEF DESCRIPTION OF THE DRAWINGS

FIG. 1 is an XRD graph of NaCl/Ta nanopowder used in an example of the present application.

FIG. 2 is a FESEM image of NaCl/Ta nanopowder used in an example of the present application.

FIG. 3 is a FESEM image of Ta nanoparticles used in an example of the present application.

FIG. 4 is a graph of time courses of photocatalytic H₂ evolution over various Ta₃N₅ materials loaded with Pt (0.1 wt. % Pt_{IMP}/0.9 wt. % Pt_{PD}).

FIG. 5 is a bar graph of initial photocatalytic H₂ evolution rates (calculated at 0.5 h) over different Ta₃N₅ specimens loaded with Pt (0.1 wt % Pt_{IMP}/0.9 wt. % Pt_{PD}).

FIGS. 6A-D are FESEM and BF-TEM images of (A) Ta₃N₅:Mg+Zr, (B) Ta₃N₅:Mg, (C) Ta₃N₅:Zr and (D) Ta₃N₅. The scale bars correspond to 200 nm.

FIGS. 7A-B are (A) FESEM and (B) BF-TEM images of Pt/Ta₃N₅:Mg+Zr (w/o NaCl).

FIGS. 8A-B are Na 1s and Cl 2p XPS spectra obtained from Ta₃N₅:Mg+Zr.

FIGS. 9A-C are XRD patterns (A-B) and Raman spectra (C) of the different Ta₃N₅ materials.

FIGS. 10A-B are Mg 1s XPS spectra of Ta₃N₅:Mg+Zr and Ta₃N₅:Mg (A) and Zr 3d XPS spectra of Ta₃N₅:Mg+Zr and Ta₃N₅:Zr (B).

FIGS. 11A-D are STEM-EDS mapping (A), TEM (B), SAED (C) and HRTEM images (D) of a cross-sectional Ta₃N₅:Mg+Zr sample.

FIG. 12 is diffuse reflectance spectra obtained using Kubelka-Munk function.

FIGS. 13A-C are Ta 4f (A), N 1s (B) and O 1s XPS core-level (C) spectra of various Ta₃N₅ materials

FIG. 14 is a graph showing proportions of different Ta_{surf} species.

FIG. 15 is a graph showing O-to-anion molar ratios.

FIG. 16 is EPR spectra of Ta₃N₅:Mg+Zr, Ta₃N₅:Mg, Ta₃N₅:Zr and Ta₃N₅.

FIG. 17 is a graph showing TA kinetic profiles for surviving electrons probed at 2000 cm⁻¹ (5000 nm) with excitation at 470 nm for different bare Ta₃N₅ materials.

FIGS. 18A-B are graphs of UV-vis DRS (A) and Tauc plots (B) obtained from various Ta₃N₅ materials.

FIGS. 19A-C are SEM images of Ta₃N₅:Mg+Zr loaded with 0.1 wt. % Pt_{IMP}/0.9 wt. % Pt_{PD} (A), 1.0 wt. % Pt_{IMP} (B), and 1.0 wt. % Pt_{PD} (C).

FIG. 20 is a bar graph of initial photocatalytic H₂ evolution rates (calculated at 0.5 h) over different Ta₃N₅ specimens.

FIGS. 21A-B are BF-TEM images of Pt@Cr2O3/Ta3N5:Mg+Zr.

FIG. 22 is graph showing time courses of photocatalytic H₂ evolution over Pt@Cr₂O₃/Ta₃N₅:Mg+Zr and Pt/Ta₃N₅:Mg+Zr.

FIG. 23 is a graph of AQY values for photocatalytic H₂ evolution over the Pt@Cr₂O₃/Ta₃N₅:Mg+Zr at various wavelengths.

### DETAILED DESCRIPTION OF THE PRESENT INVENTION

The present invention is directed to tantalum nitride nanoparticles that are doped with at least one metal, such as two metals or more than two metals. The nanoparticles can be a catalyst alone or be part of a catalyst. The catalyst can be used in various methods, such as methods to water split. The present invention is further directed to methods of making the tantalum nitride nanoparticles and the catalyst.

The tantalum nitride can be a n-type semiconductor, preferably with a narrow bandgap and/or suitable energetic positions of conduction and valance bands straddling the water redox potentials.

The nanoparticles of the present invention can be single crystalline nanoparticles doped with at least one metal. The nanoparticles of the present invention can be single crystalline tantalum nitride nanoparticles doped with at least one metal.

The nanoparticles can be monodispersed nanoparticles, such as single crystalline monodispersed nanoparticles.

The nanoparticles can be a tantalum nitride nanoparticle (e.g., single crystalline nanoparticle) doped with at least one metal (e.g., at least one metal, or at least two metals, or at least three or more metals).

As a more specific example, the nanoparticle can be single crystalline tantalum nitride nanoparticles co-doped with two metals. The two metals can be Zr and Mg.

Other examples of the one or more metals that can be used as the doped metal can be Li, Sc, Ti, Hf, Al, and/or Ga and/or any combinations thereof.

A specific example of a tantalum nitride is Ta₃N₅.

Other examples of tantalum nitride include, but are not limited to, Ta₄N₅, Ta₅N₆, Ta₂N, and TaN and generally TaN, where x ranges from 0.1 to 3.

With respect to the doped metal or metals, preferably, the at least one metal (i.e., doped metal) reside as a cation(s) in a crystal lattice of the tantalum nitride.

More specific examples of a tantalum nitride (with doped metals) are Ta₃N₅:Mg+Zr, or Ta₃N₅:Mg, or Ta₃N₅:Zr or any combinations thereof.

And, as a further example, all of the Mg²⁺ and/or Zr⁴⁺ cations reside in the crystal lattice of Ta₃N₅.

The tantalum nitride can be Ta₃N₅:Mg+Zr alone. The tantalum nitride can be Ta₃N₅:Mg alone. The tantalum nitride can be Ta₃N₅:Zr alone. Each of these can be single crystalline nanoparticles. Each of these can have the Mg and/or Zr residing as cations in the crystal lattice of the Ta₃N₅.

When more than one tantalum nitride is present in the population of nanoparticles, the distribution between two or more different tantalum nitrides can be even or uneven. For instance, the Ta₃N₅:Mg+Zr can be present in the highest weight percent based on the total weight of all tantalum nitrides present.

The single crystalline nanoparticles of the present invention can exhibit single-phase X-ray diffraction (XRD) patterns associated with anosovite-type tantalum nitride, such as anosovite-type Ta₃N₅.

As an option, the single crystalline nanoparticles (such as Ta₃N₅:Mg+Zr, or Ta₃N₅:Mg, or Ta₃N₅:Zr) can be where EPR-active Ta⁴⁺ is not present (e.g., not present at −173.15° C.).

The single crystalline nanoparticles of the present invention can have a variety of shapes. For instance, the nanoparticles can have a shape such that the nanoparticles are considered monodispersed nanorod particles.

When nanoparticles are nanorod particles, the nanorod particles can have a length. The length can be from 50 nm to 500 nm, such as from 50 nm to 450 nm, from 50 nm to 400 nm, from 50 nm to 350 nm, from 50 nm to 300 nm, from 50 nm to 250 nm, from 50 nm to 200 nm, from 50 nm to 150 nm, from 75 nm to 500 nm, from 100 nm to 500 nm, from 125 nm to 500 nm, from 150 nm to 500 nm, from 175 nm to 500 nm, from 200 nm to 500 nm, from 225 nm to 500 nm, from 250 nm to 500 nm, from 275 nm to 500 nm, from 300 nm to 500 nm and the like. The length can be considered an average length.

When the nanoparticles are nanorods, the nanorods can have an aspect ratio (length/width) of at least 1.2 (e.g., at least 1.3, or at least 1.4, or at least 1.5, or at least 1.7, or at least 2 or at least 2.5, or at least 3, or at least 4 such as from 1.2 to 4 or higher, or from 1.3 to 4, or from 1.4 to 4 and the like).

When the tantalum nitride is Ta₃N₅:Mg+Zr, or Ta₃N₅:Mg, or Ta₃N₅:Zr or any combinations thereof, the tantalum nitride can have Mg-to-cation (e.g., Mg/(Ta+Mg+Zr)) and Zr-to-cation (e.g., Zr/(Ta+Mg+Zr)) ratios that are as high as 9.0 mol. % and 10.2 mol. %, respectively. Mg-to-cation ratio can be from 1 to 9 mol % or from 2 to 9 mol % or from 3 to 9 mol % or from 4 to 9 mol % or from 5 to 9 mol % or from 6 to 9 mol %. The Zr-to-cation ration can be from 1 to 10.2 mol %, from 2 to 10 mol %, from 3 to 10 mol %, from 4 to 10 mol %, from 5 to 10 mol %, from 6 to 10 mol %, from 7 to 10 mol %, or from 8 to 10 mol %.

The present invention also relates to TaNₓ:M1 or TaNₓ:M1+M2 or any combinations thereof, where x ranges from 0.1 to 3, M1 and M2 represent a metal cation (e.g., Mg, Zr, Li, Sc, Ti, Hf, Al, or Ga) and M1 and M2 are not the same.

As an option, the tantalum nitride (e.g., Ta₃N₅:Mg+Zr, or Ta₃N₅:Mg, or Ta₃N₅:Zr or any combinations thereof) can have minor segregated phases of MgO, Zr₂ON₂, NaTaO₃ and/or ZrO₂ not present (i.e., not detectable or 0%).

As an option, the tantalum nitride (e.g., Ta₃N₅:Mg+Zr, or Ta₃N₅:Mg, or Ta₃N₅:Zr or any combinations thereof) can be a tantalum nitride in the substantial or detectable absence of one or more of the following minor segregated phases: MgO, Zr₂ON₂, NaTaO₃, and/or ZrO₃. A ‘substantial absence’ being no detectable response within the XRD pattern of the tantalum nitride.

As an option, the tantalum nitride (e.g., Ta₃N₅:Mg+Zr, or Ta₃N₅:Mg, or Ta₃N₅:Zr or any combinations thereof) can have an atomic ratio of surface Ta in the form of Ta₃N₅ (N—Ta—N) that is over 90 at % (e.g., such as 91 at % or higher, or 92 at % or higher, or 95 at % or higher or from 91 at % to 99 at % or from 91 at % to 98 at %, or 92 at % to 98 at %, or 93 at % to 98 at %, or 94 at % to 98 at %).

As an option, the tantalum nitride (e.g., Ta₃N₅:Mg+Zr, or Ta₃N₅:Mg, or Ta₃N₅:Zr or any combinations thereof) can have an atomic ratio of surface Ta in the form of Ta“that is below 1 at % (e.g., 0.9 at % or lower, or 0.8 at % or lower, or 0.5 at % or lower, such as 0.001 at % to 0.9 at % or 0.01 at % to 0.5 at %). The atomic ratio of surface Ta in the form of Ta” can be undetectable or below 0.001 at %.

As an option, the tantalum nitride (e.g., Ta₃N₅:Mg+Zr, or Ta₃N₅:Mg, or Ta₃N₅:Zr or any combinations thereof) can have an atomic ratio of surface Ta in the form of TaOₓN_{y} (O—Ta—N) that is 2 at % or more. The atomic ratio can be from 2 at % to 5 at %. x and y here are such that the N/O is preferably greater than 2, or greater than 3, or greater than 4 or greater than 4.5 or greater than 4.8.

The crystalline particles of the present invention, such as a doped tantalum nitride, have a charge imbalance resulting in an oxygen-to-anion (O/N+O) molar ratio of 3.0% or higher or 4.0% or higher, such as from 3.0% to about 18% or from 5% to about 18%, or from about 7% to about 18%, or from about 10% to about 18% or from about 12% to about 18% or from 15% or higher.

As an option, the tantalum nitride (e.g., Ta₃N₅:Mg+Zr, or Ta₃N₅:Mg, or Ta₃N₅:Zr or any combinations thereof) can have a charge imbalance resulting in an oxygen-to-anion (O/N+O) molar ratio of 4.0% or higher (e.g., such as a molar ratio of from 5.0% to about 18%, or from 6.0% to 18%, or from 7.0% to 18%, or from 8.0% to 18%, or from 9.0% to 18%, or from 10% to 18% and the like).

As an option, the tantalum nitride (e.g., Ta₃N₅:Mg+Zr, or Ta₃N₅:Mg, or Ta₃N₅:Zr or any combinations thereof) can have a transient absorption (TA) kinetic profile of charged particles that is higher than undoped Ta₃N₅. The TA kinetic profile can be based on TA kinetic profiles of surviving electrons probed at 2000 cm⁻¹ (5000 nm) under 470 nm excitation. The TA kinetic profile(s) for the nanoparticles of the present invention can be 5% or more, 10% or more, 15% or more, 20% or more, 25% or more, 30% or more, 35% or more, 40% or more, 45% or more, or 50% or more higher with respect to the delta absorbance and/or the decay time (ms). See FIG. 17 for an example of these higher TA profiles.

As an option, the tantalum nitride (e.g., Ta₃N₅:Mg+Zr, or Ta₃N₅:Mg, or Ta₃N₅:Zr or any combinations thereof) can have an evolved H₂ with a rate (R_{H2}) of at least 2 μmol/h where such rates are based on a Pt loading of 0.9 wt % Pt based on the total weight of the tantalum nanoparticles and the Pt particles having an average size of from about 2 mm to about 5 nm. The evolved H₂ with a rate (R_{H2}) can be from 10 μmol/h to 70 μmol/h or more, or from 2 μmol/h to 60 μmol/h, or from 2 μmol/h to 50 μmol/h, or from 2 μmol/h to 40 μmol/h, or from 2 μmol/h to 30 μmol/h, or from 2 μmol/h to 20 μmol/h, or from 2 μmol/h to 10 μmol/h, or from 5 μmol/h to 70 μmol/h, or from 10 μmol/h to 70 μmol/h, or from 15 μmol/h to 70 μmol/h, or from 20 μmol/h to 70 μmol/h, or from 25 μmol/h to 70 μmol/h, or from 30 μmol/h to 70 μmol/h, or from 35 μmol/h to 70 μmol/h, or from 40 μmol/h to 70 μmol/h.

As an option, the tantalum nitride (e.g., Ta₃N₅:Mg+Zr, or Ta₃N₅:Mg, or Ta₃N₅:Zr or any combinations thereof) can be a tantalum nitride in the substantial or detectable absence of one or more of the following defect species: a reduced species such as Ta³⁺ or Ta⁴⁺, or V_{N}, or O_{N}. A ‘substantial absence’ can be less than less than 15 at % or less than 10 at % or less than 5 at % or less than 2.5 at % or less than 1.5 at % or less than 1 at % or less than 0.5 at %. V_{N} represents a nitrogen vacancy, and can be V_{N}^{●●●}, V_{N}^{●●}, V_{N}^{●} and V_{NØ}. And, V_{N}^{●●●}, V_{N}^{●●}, V_{N}^{●} and V_{NØ} represent the V_{N} with zero, one, two and three trapped electrons, respectively, and that only V_{N}^{●●} and V_{NØ} with unpaired electrons are possibly EPR-active. ON represents an oxygen impurity (examples include O²⁻).

The tantalum nitride(s) of the present invention can be or serve as a catalyst alone or as an option, can be part of a catalyst. The tantalum nitride of the present invention as a catalyst can be used with one or more co-catalyst.

The catalyst of the present invention can be a photocatalyst. The photocatalyst can be active with various light waves or light regions, such as ultraviolet light and/or visible light (i.e., visible-light region).

The co-catalyst can be a metal co-catalyst. The co-catalyst can be platinum (Pt). The co-catalyst can be a metal such as, but not limited to, gold, platinum, cobalt, palladium, silver, nickel or any combinations thereof. The co-catalyst can be Cr₂O₃.

A co-catalyst such as a metal co-catalyst (e.g., Pt) can be used in combination with another co-catalyst, such as Cr₂O₃.

The tantalum nitride(s) of the present invention can be or serve as a catalyst alone, such as photocatalyst and optionally has the ability to split water without the assistance of cocatalysts.

The tantalum nitride(s) of the present invention can be or serve as a catalyst alone, such as photocatalyst and optionally has the ability to split water without using sacrificial reagents.

The tantalum nitride(s) of the present invention can be or serve as a catalyst alone, such as photocatalyst and optionally has the ability to split water under ultraviolet irradiation or under visible light.

The catalyst of the present invention comprises, consists essentially of, consists of, includes, or is single crystalline nanoparticles of the present invention.

The catalyst of the present invention can further comprise or include one or more co-catalysts.

The co-catalyst can be one or more metal-based or metal-containing or metal co-catalyst. As indicated, the co-catalyst can be platinum (Pt). The co-catalyst can be a metal such as, but not limited to, gold, platinum, cobalt, palladium, silver, nickel or any combinations thereof.

The co-catalyst can be distributed or dispersed on the nanoparticles, such as homogeneously distributed or dispersed on the single crystalline nanoparticles. In the alternative or additionally, the co-catalyst can be mixed with the nanoparticles or used in combination with the nanoparticles in any fashion.

The co-catalyst can be platinum (Pt) distributed or dispersed on the nanoparticles, such as homogeneously distributed or dispersed on the single crystalline nanoparticles.

Preferably, the co-catalyst, such as Pt, is evenly distributed on the surface of the single crystalline nanoparticles (e.g., a variance of ±10% by weight of Pt or other co-catalyst anywhere on the surface). As an option, no aggregation of the co-catalyst (e.g., Pt) or the aggregation of co-catalyst (e.g., Pt) with nanoparticles is detectable.

The catalyst can have a solar-to-hydrogen (STH) energy conversion efficiency of over 0.015%. For instance, the STH energy conversion efficiency can be from 0.015% to 0.1%, such as from 0.02% to 0.1%, or from 0.03% to 0.1% or from 0.04% to 0.1% or from 0.05% to 0.1% or from 0.06% to 0.1%.

The catalyst can have an H₂ production that is over 5 μmol/h. The H₂ production can be from 5 μmol/h to 13 μmol/h or 6 μmol/h to 13 μmol/h, or from 7 μmol/h to 13 μmol/h or from 8 μmol/h to 13 μmol/h and the like.

The catalyst of can have a higher photocatalytic water reduction activity than pristine Ta₃N₅ under visible-light irradiation. The higher activity can be 5% or more higher or 10% or more higher or 15% or more higher.

The catalyst can have an apparent quantum yield (AQY) at 420 nm of over 0.15% for photocatalytic H₂ evolution reaction (HER). The AQY at 420 nm can be from 0.15% to 0.54% or from 0.2% to 0.54%, or from 0.3% to 0.54%.

The method to make the catalyst with co-catalyst includes or involves the co-catalyst loading (e.g., Pt loading) of the single crystalline nanoparticles.

The co-catalyst loading (e.g., Pt loading) can involve or include the deposition of one or more co-catalyst (e.g., Pt) by an impregnation-reduction (IMP) method. This method involves dispersing the tantalum nitride with a co-catalyst containing compound or co-catalyst precursor (e.g., Pt containing compound or Pt precursor such as H₂PtCl₆) to form a slurry which can be heated with hot water vapor such as steam until dry. The powder can be then heated at 250° C. for 1 h under a H₂/N₂ gaseous flow (H₂: 20 mL/min; N₂: 200 mL/min) so as to obtain the co-catalyst loaded tantalum nitride (e.g., PtIMP/Ta₃N₅).

The co-catalyst loading (e.g., the Pt loading) can involve or include the deposition of co-catalyst (e.g., Pt) by an in-situ photodeposition (PD) method. In this method, the co-catalyst precursor (e.g., Pt precursor) can be added to an aqueous solution containing the tantalum nitride nanoparticles. The co-catalyst (e.g., Pt) can be loaded onto the tantalum nitride nanoparticles in-situ under photocatalytic reaction conditions.

The co-catalyst loading (e.g., Pt loading) can be a combination of the IMP and PD methods. For instance, the co-catalyst loading (e.g., Pt loading) can be in a stepwise method. The IMP-PD stepwise method can involve the deposition of the co-catalyst (e.g., Pt) by IMP as the seed (first step) and further seed growth of the co-catalyst (e.g., Pt) by in-situ PD (second step).

In a combination of IMP and PD methods, the co-catalyst loading (e.g., Pt loading) by the photodeposition (PD) method can account for from 70% to 95% of total co-catalyst loading by wt % of co-catalyst (e.g., Pt loading by wt % Pt).

The catalyst of the present invention can be use in methods to split water or other fluids (such as an aqueous fluid, and where fluid refers to a liquid or gas) and thus produce, for instance, hydrogen (e.g., in the form of hydrogen gas or hydrogen protons). The method can form also oxygen (e.g., in the form of oxygen gas or oxygen molecules).

The aqueous fluid can be water. The aqueous fluid can be a water-based fluid. The aqueous fluid can be an alcohol.

The method can comprise or include applying energy to the water or aqueous fluid in the presence of the catalyst to drive the splitting of water molecules into protons (H+), electrons, and oxygen gas.

The energy source can be solar energy. The energy source can be light energy. The energy source can be ultra-violet light. The energy source can be visible light. The energy source can be infrared (IR) energy. The energy source can be visible-light irradiation. The energy source can provide irradiation that is at least 20 mW/cm² or at least 40 mW/cm² or at least 60 mW/cm² or at least 80 mW/cm² or at least 100 mW/cm².

The catalyst can be suspended or otherwise present in the water or aqueous fluid or other fluid.

The catalyst can be attached to a surface and in contact with the water or aqueous fluid or other fluid.

The water or aqueous fluid or other fluid can be moving or stationary relative to the catalyst.

The catalyst can be present in any amounts. For instance, when the catalyst is suspended in water or aqueous fluid or other fluid, the amount can be at least 0.15 g/150 ml fluid or at least 0.2 g/150 ml, or at least 0.5 g/150 ml or other amounts below or above any one of these ranges. Similar amounts can be used when the catalyst is fixed to a surface.

The present invention further relates to a method to make the nanoparticles of the present invention.

The method can comprise, consists of, consists essentially of, or include impregnating a tantalum powder (such as a salt encapsulated tantalum powder) (e.g., NaCl/Ta) with MgCl₂ or other first metal salt and ZrOCl₂ or other second metal salt and then conducting nitridation or nitriding under a flow of gas.

The salt-encapsulated tantalum powder, such as NaCl/Ta, can be a NaCl-encapsulated Ta from a sodium/halide flame encapsulation method.

The method for forming the starting tantalum can be a tantalum production process that includes or is sodium/halide flame encapsulation (SFE). Techniques employed for the SFE process which can be adapted for preparation of starting tantalum powder for the present invention are described in U.S. Pat. Nos. 5,498,446 and 7,442,227, which are incorporated in their entireties by reference herein. See, also, Barr, J. L. et al., “Processing salt-encapsulated tantalum nanoparticles for high purity, ultra-high surface area applications,” J. Nanoparticle Res. (2006), 8:11-22. An example of the chemistry employed for the production of metal powder by the SFE process of the '446 patent is as follows, wherein “M” refers to a metal such as Ta: MClₓ+XNa+Inert→M+XNaCl+Inert. Tantalum pentachloride is an example of a tantalum halide that can be used as the reactant MClₓ, and argon gas may be used as the Inert and carrying gas, in this chemistry. Initially, particles (e.g., Ta) are produced at the flame and grow by coagulation while the salt remains in the vapor phase. The salt condenses onto and/or around the Ta particles with heat loss, and uncoated core particles can be scavenged by the salt particles.

With respect to the nitriding step, the gas for the flow of gas can be a nitrogen containing gas, such as NH₃. The flow rate of the gas can be 100 ml/min or more, 150 ml/min or more, or 200 ml/min or more.

The nitriding can be conducted at an elevated temperature, such as above 500 deg C. or higher, or 600 deg C. or higher, or 700 deg C. or higher, or 800 deg C. or higher, or 900 deg C. or higher, or at a temperature from 500 deg C. to 1,100 deg C., or from 600 deg C. to 1,100 deg C., or from 700 deg C. to 1,100 deg C., or from 800 deg C. to 1,100 deg C., or from 900 deg C. to 1,200 deg C.

The present invention will be further clarified by the following examples, which are intended to be purely exemplary of the present invention.

### EXAMPLES

### Example 1

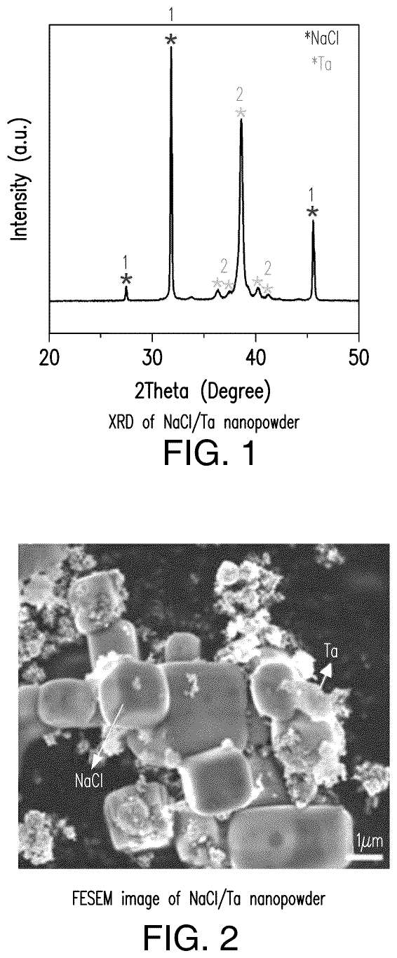

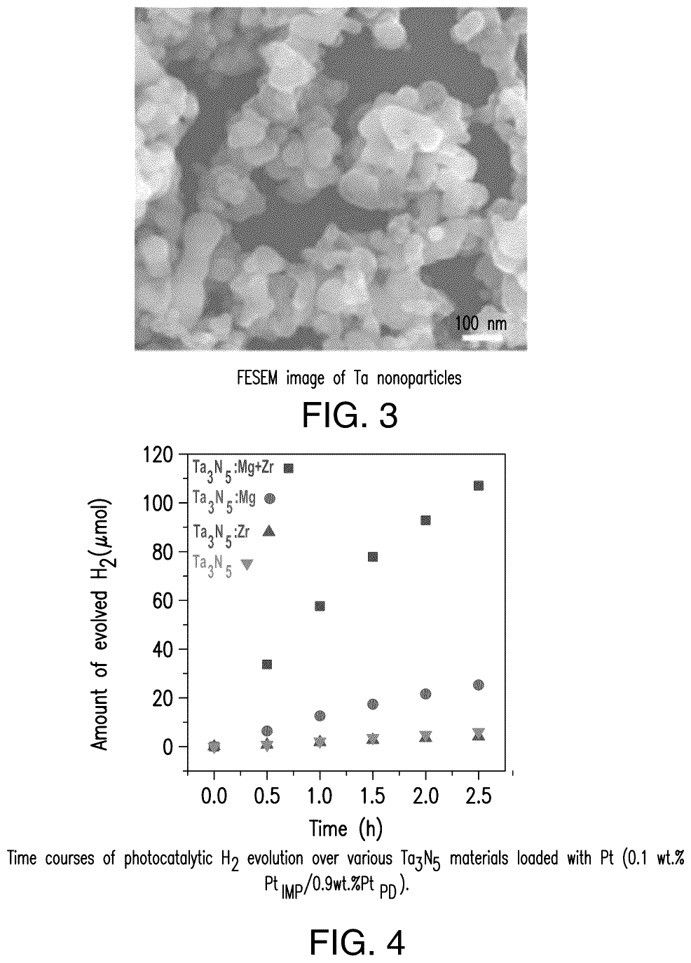

Ta Nanopowder Precursor. NaCl-contained Ta nanopowder (NaCl/Ta) and Ta nanopowder without NaCl (w/o NaCl/Ta), the precursors for Ta₃N₅ synthesis, were used and available from Global Advanced Metals USA, Inc. The NaCl/Ta material was mainly characterized with micron-sized NaCl crystals surrounded by aggregated spherical Ta nanoparticles (FIG. 1 and FIG. 2). The molar ratio of NaCl/Ta was determined to be 4.5 according to the inductively coupled plasma-atomic emission spectroscopy (ICP-AES; ICPS-8100, Shimadzu) analysis. The w/o NaCl/Ta material was mainly characterized by aggregated spherical Ta nanoparticles (FIG. 3).

Synthesis of Doped Ta₃N₅. 0.67 g of NaCl/Ta was well mixed with 92.1 μL of aqueous MgCl2 solution (2 M; Sigma-Aldrich BioUltra), 92.1 μL aqueous ZrOCl2 solution (2 M; Fujifilm Wako Pure Chemical Industries, Ltd.) and 300 μL of ultrapure H₂O in an agate mortar. The feed molar ratio of Ta/Mg/Zr was about 7.5/1/1. After desiccating the mixture by mild heating at 60° C. and grinding for around 20 min, the solid was carefully loaded into an alumina crucible, and further heated to 900° C. with a ramping rate of 10° C./min and held at 900° C. for 3 h under a gaseous NH₃ flow of 200 mL/min. After natural cooling to room temperature, the obtained sample was washed with hot water (70° C.), and then dried at 40° C. for 6 h under vacuum conditions. Ta₃N₅:Mg+Zr (feed molar ratio of Ta/Mg/Zr=7.5/1/1) was obtained. Ta₃N₅:Mg (feed molar ratio of Ta/Mg=7.5/1), Ta₃N₅:Zr (feed molar ratio of Ta/Zr=7.5/1) and Ta₃N₅ were synthesized using the same procedures adjusting the amount of MgCl₂ solution and/or ZrOCl₂ solution to achieve the desired molar ratios. Following the same procedure, but replacing the NaCl/Ta with the w/o NaCl/Ta, and adjusting the amount of MgCl₂ solution and ZrOCl₂ solution to achieve the desired molar ratios, the material Ta₃N₅:Mg+Zr (w/o NaCl) (feed molar ratio of Ta/Mg/Zr=7.5/1/1) was obtained. The materials Ta₃N₅:Mg+Zr, Ta₃N₅:Mg, Ta₃N₅:Zr, Ta₃N₅, and Ta₃N₅:Mg+Zr (w/o NaCl) are collectively the Doped Ta₃N₅.

Synthesis of Cocatalyst Doped Ta₃N₅. Pt as the hydrogen evolution cocatalyst was loaded onto the surface of the Doped Ta₃N₅ by a stepwise process utilizing an impregnation-H₂ thermal reduction (IMP) method followed by an in-situ photodeposition (PD) method. For the IMP method, Doped Ta₃N₅ was first well-dispersed in an aqueous solution containing the required amount of H₂PtCl₆ as the Pt precursor by sonication for 1 min. The slurry was further heated by hot water vapor under manual stirring using a glass rod until it turned dry. After heating the powder at 250° C. for 1 h under a H₂/N₂ gaseous flow (H₂: 20 mL/min; N₂: 200 mL/min), the sample PtIMP/Doped Ta₃N₅ was obtained with a Pt IMP loading of 0.1 wt %. Following, a required amount of H₂PtCl₆ was added to an aqueous reaction solution containing PtIMP/Doped Ta₃N₅ photocatalyst. Pt was loaded onto PtIMP/Doped Ta₃N₅ in-situ under photocatalytic reaction conditions. The Pt loading by PD method was 0.9 wt. %. The resulting catalysts were the Doped Ta₃N₅ loaded with a total of 1.0 wt % Pt; 0.1 wt % Pt by IMP and 0.9 wt % Pt by PD. The Doped Ta₃N₅ are designated as Pt/Ta₃N₅:Mg+Zr, Pt/Ta₃N₅:Mg, Pt/Ta₃N₅:Zr, Pt/Ta₃N₅, and Pt/Ta₃N₅:Mg+Zr (w/o NaCl)

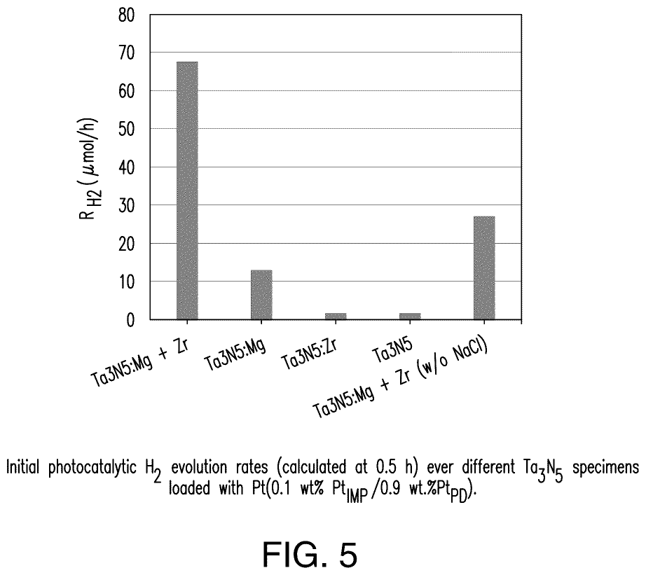

Photocatalytic H₂ Evolution Reaction. All photocatalytic reactions were carried out at 12° C. implemented by a cooling water system in a Pyrex top-illuminated reaction vessel connected to a closed gas-circulation system. 0.15 g of the Pt Cocatalyst Doped Ta₃N₅ were each well-dispersed in 150 mL aqueous methanol solution (130 mL H₂O+20 mL MeOH) with a pH value of around 7. After completely degassing the reaction slurry by evacuation, a required amount of argon gas was introduced to create a background pressure of ca. 7 kPa, and the reactant solution was irradiated with a 300 W xenon lamp equipped with a cold mirror and a cut-off filter (L42, λ≥420 nm). The evolved gas products were analyzed by an integrated online thermal-conductivity-detector gas chromatography system consisting of a GC-8A chromatograph (Shimadzu) equipped with molecular sieve 5 Å columns, with argon as the carrier gas. FIG. 4 showed the evolution rate curves for the different catalysts. The rate of hydrogen produced was found to be Pt/Ta₃N₅:Mg+Zr>>Pt/Ta₃N₅:Mg+Zr (w/o NaCl)>>Pt/Ta₃N₅:Mg>>Pt/Ta₃N₅:Zr≈Pt/Ta₃N₅ (FIG. 5) Pt/Ta₃N₅:Mg+Zr evolved H₂ with a rate (RH₂) of 67.3 μmol/h, which was 45 times higher than that of Pt/Ta₃N₅ (1.5 μmol/h).

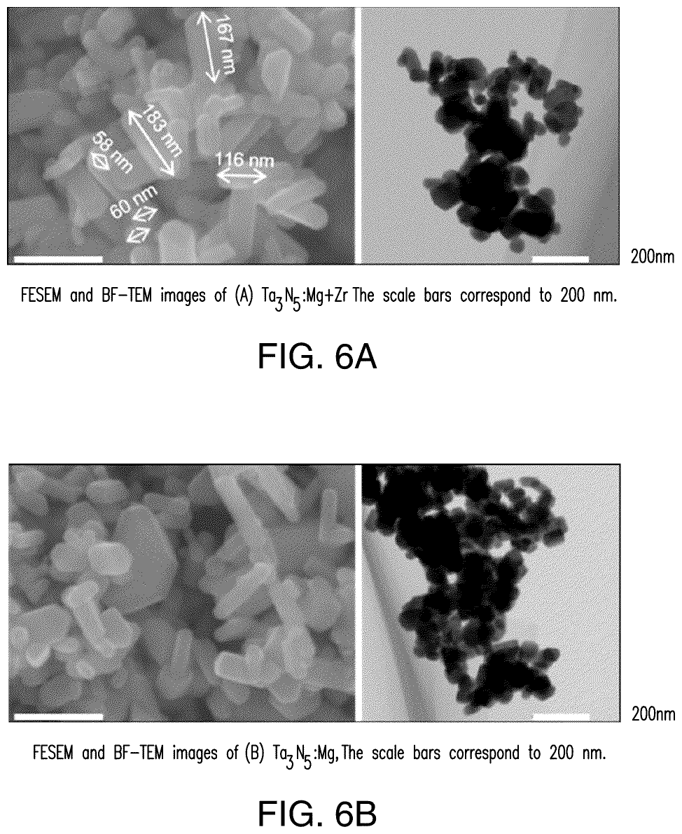

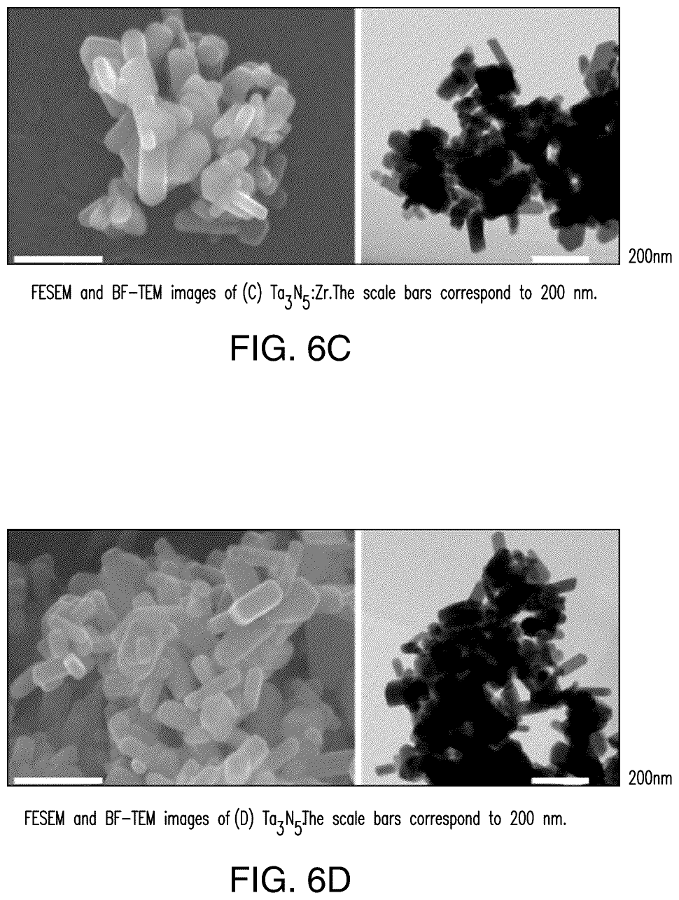

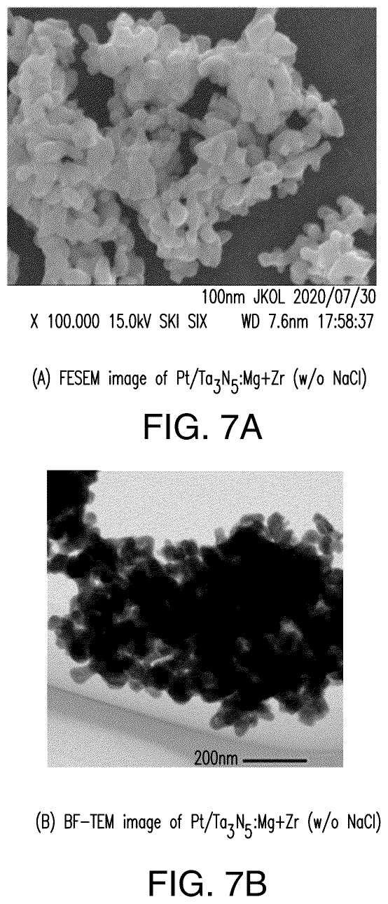

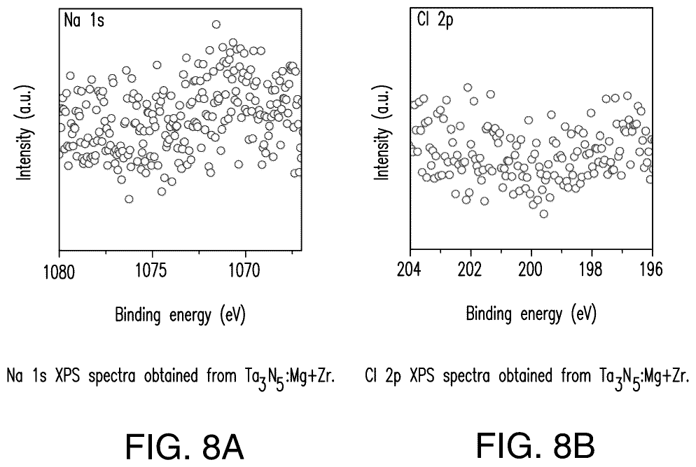

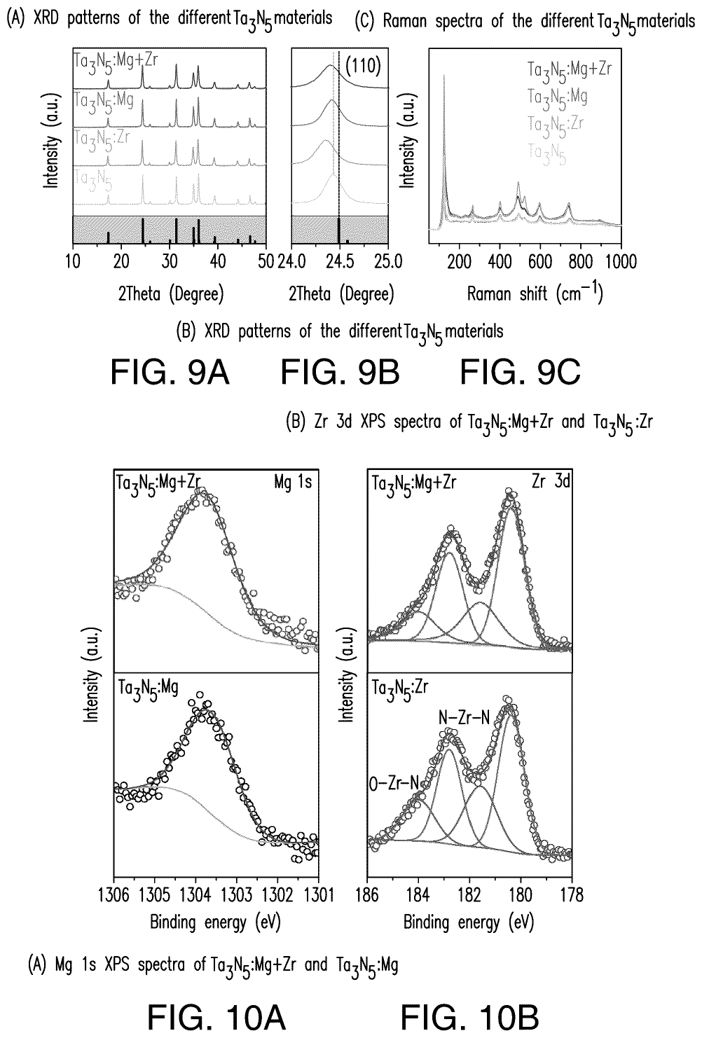

Single Crystal Characterization. The materials Pt/Ta₃N₅:Mg+Zr, Pt/Ta₃N₅:Mg, Pt/Ta₃N₅:Zr, and Pt/Ta₃N₅, were distinctly different than the Pt/Ta₃N₅:Mg+Zr (w/o NaCl) The Pt/Ta₃N₅:Mg+Zr, Pt/Ta₃N₅:Mg, Pt/Ta₃N₅:Zr, and Pt/Ta₃N₅ were monodispersed nanorod-like particles having about 50-200 nm in length as the major product (FIGS. 6A-D), while the Pt/Ta₃N₅:Mg+Zr (w/o NaCl) were irregularly-shaped particles (FIGS. 7A-B). It is believed that the salt (e.g., NaCl) served as a type of molten salt flux during the nitridation process, playing an important role in the formation of the monodispersed nanorods. Further, it was observed with the monodispersed nanorod-like particles that XPS spectra demonstrated no strong signal for Na or Cl indicating neither Na nor Cl atoms were incorporated into the framework of Ta₃N₅:Mg+Zr (FIGS. 8A-B) The crystal phases were examined by X-ray diffraction (XRD) using a Rigaku MiniFlex 300 powder diffractometer with a Cu Kα1 radiation source (λ=1.5406 Å). Raman spectra were recorded with a LabRam micro-spectrometer iHR 550 (Horiba Jobin Yvon) using an entrance slit of 200 μm, 1800 l/mm grating and a 660 nm laser with an intensity of 2.8×10⁵ W/cm². The oxygen and nitrogen contents of the synthesized Ta₃N₅ were measured by an oxygen-nitrogen combustion analyzer (Horiba, EMGA-620W). The Ta₃N₅:Mg+Zr, Ta₃N₅:Mg, Ta₃N₅:Zr, and Ta₃N₅ all exhibited single-phase X-ray diffraction (XRD) patterns associated with anosovite-type Ta₃N₅ (FIGS. 9A-C), even though the practically incorporated Mg-to-cation (Mg/(Ta+Mg+Zr)) and Zr-to-cation (Zr/(Ta+Mg+Zr)) ratios reached as high as 9.0 mol. % and 10.2 mol. %, respectively (Table 1). Raman spectroscopy, which is more sensitive in distinguishing the crystal phase by analysis of lattice dynamical properties, was further used and the result corroborated the single Ta₃N₅ phase of Ta₃N₅:Mg+Zr, as only Raman modes of Ta₃N₅ were observed (FIGS. 9A-C). This indicates that all Mg²⁺ and Zr⁴⁺ cations reside in the crystal lattice of Ta₃N₅ which is also reflected by the successful detection of lattice Mg²⁺ and Zr⁴⁺ on surface (FIGS. 10A-B) and the shift of (110) XRD peak toward a lower angle (FIGS. 9A-C).

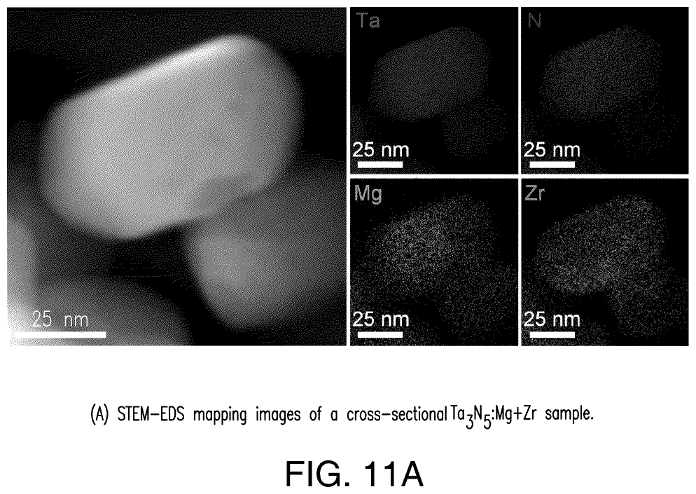

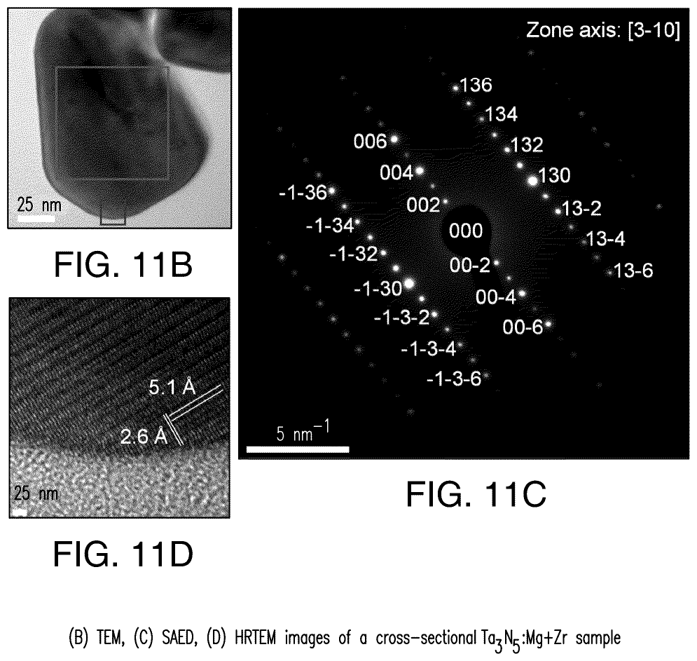

Scanning electron microscopy (SEM) images were taken on a JOEL JSM-7600F field-emission (FE) SEM instrument operated at an acceleration voltage of 15 kV or a Hitachi SU8000 FESEM instrument operated at an acceleration voltage of 30 kV. (Scanning) transmission electron microscopy ((S)TEM) images, energy-dispersive X-ray spectrometry (EDS) mapping images and selected area electron diffraction (SAED) patterns were recorded using a JEOL JEM-2800 system. The cross-sectional sample for (S)TEM observation was made by Ar ion milling using a JOEL EM-09100IS ion slicer. Scanning-transmission electron microscopy coupled with energy dispersive X-ray spectrometry (STEM-EDS) mapping of the cross-section of Ta₃N₅:Mg+Zr (FIG. 11A) confirmed almost even distribution of Mg and Zr dopants within the Ta₃N₅ particle body. Well-defined selected area electron diffraction (SAED) patterns (FIG. 11) and clear lattice fringes up to the outmost surface (FIG. 11D) were observed for a cross-sectional Ta₃N₅:Mg+Zr sample by high-resolution (HR) TEM (FIG. 11B).

All of this provided the conclusion that the prepared Ta₃N₅:Mg+Zr comprised of Mg- and Zr-co-doped single-crystalline Ta₃N₅ nanoparticles. No minor segregated phases such as MgO, Zr₂ON₂, NaTaO₃ and ZrO₂ were observed in the formed Ta₃N₅:Mg+Zr.

Defect Species Analysis. Reduced Ta species (Ta³⁺ and/or Ta⁴⁺), nitrogen vacancy V_{N} (V_{N}^{●●●}, V_{N}^{●●}, V_{N}^{●} and V_{NØ}) and oxygen impurity O_{N}, are the defect species impacting the photocatalytic performance of Ta₃N₅, and were comprehensively detected mainly by X-ray photoelectron spectroscopy (XPS; for reduced Ta), electron paramagnetic resonance spectroscopy (EPR; for reduced Ta and V_{N}) and combustion analysis (for ON). Note that V_{N}^{●●●}, V_{N}^{●●}, V_{N}^{●} and V_{NØ} represent the V_{N} with zero, one, two and three trapped electrons, respectively, and that only V_{N}^{●●} and V_{NØ} with unpaired electrons are possibly EPR-active. X-ray photoelectron spectra (XPS) were acquired using a PHI Quantera II spectrometer with an Al Kα radiation source. All binding energies were referenced to the C Is peak (284.8 eV) arising from adventitious carbon. Electron paramagnetic resonance (EPR) spectra were recorded on an X-band ELEXSYS 500-10/12 CW-spectrometer (Bruker) using a microwave power of 6.3 mW, a modulation frequency of 100 kHz and an amplitude up to 5 G. Standard EPR tubes were each filled with 100 mg of the individual photocatalyst under Ar and measured at 20° C. The oxygen and nitrogen contents of the synthesized Ta₃N₅ were measured by an oxygen-nitrogen combustion analyzer (Horiba, EMGA-620W). Diffuse reflectance spectra (DRS) were acquired using an ultraviolet-visible-near-infrared spectrometer (V-670, JASCO) and further converted from reflectance into the Kubelka-Munk (K.-M.) function.

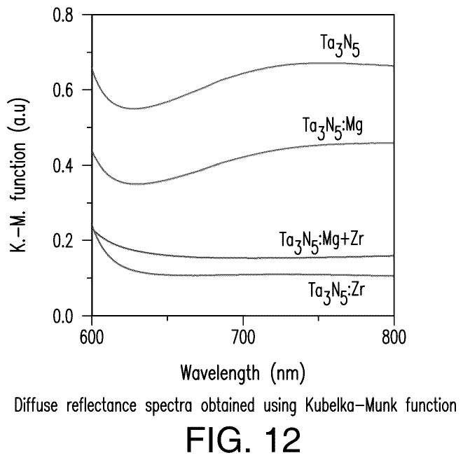

The background absorbance of different Ta₃N₅ at 600-800 nm region, arising from defect species, was compared in FIG. 12. Mg and/or Zr doping reduced the defect species in Ta₃N₅, characterized by lower background absorption intensities (FIG. 12), and this was more valid for Ta₃N₅:Zr and Ta₃N₅:Mg+Zr.

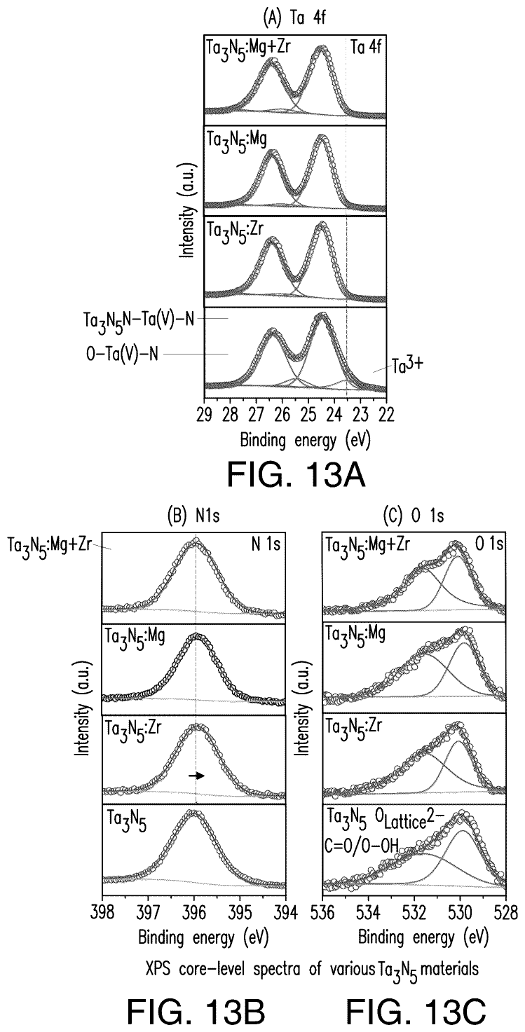

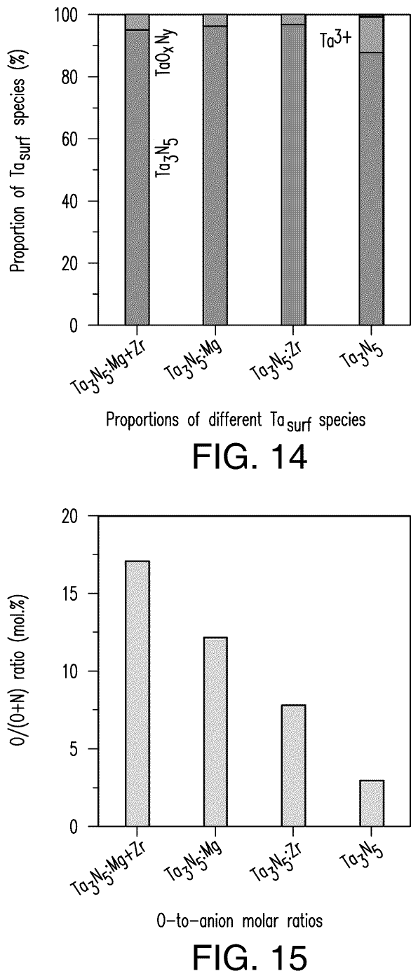

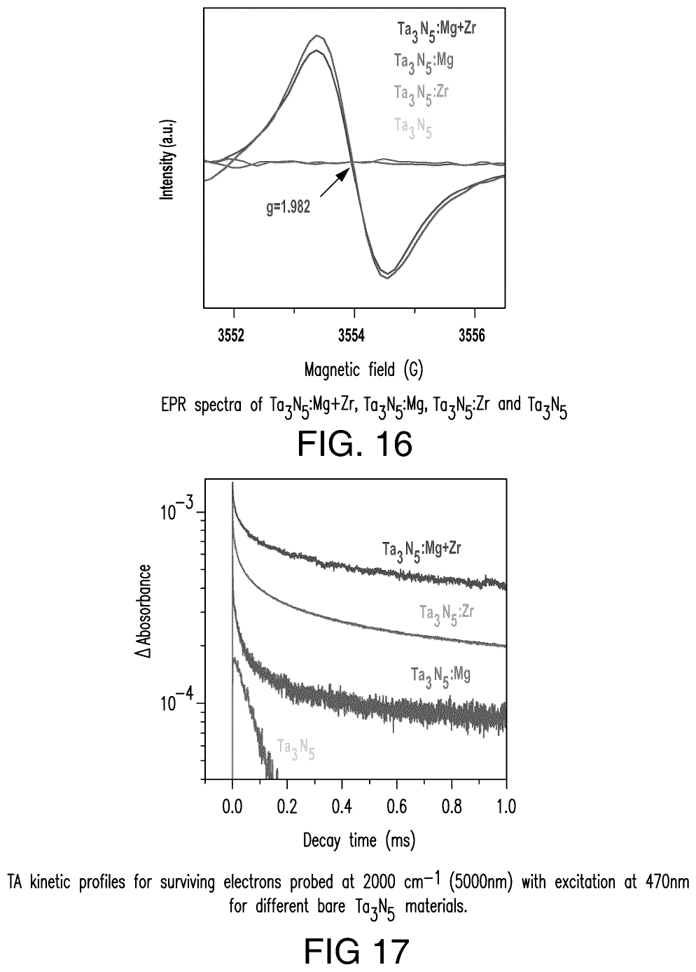

One major defect species suppressed by doping was found to be Ta³⁺. This is the case because a Ta 4f7/2 component was identified with a binding energy of 23.6 eV in undoped Ta₃N₅ (FIG. 13A) that was assigned to Ta³⁺, and EPR-active Ta⁴⁺ was not found by EPR even at −173.15° C. Further details about the XPS interpretation are shown in FIGS. 13B-C, and quantitative XPS results of surface Ta species deriving from the peak area (Table 2) are shown in FIG. 14. The atomic ratios of surface Ta in the form of Ta₃N₅ (N—Ta—N), Ta³⁺ and TaOxNy (O—Ta—N) in undoped Ta₃N₅ were estimated to be 85.5%, 12.8% and 1.7%, respectively. With Mg or/and Zr doping, Ta³⁺ was completely eliminated, and the surface fraction of Ta₃N₅ (N—Ta—N) significantly increased (FIG. 14). Formation of Ta³⁺ in pristine Ta₃N₅ or substitution of Ta⁵⁺ by low-valence Mg²⁺/Zr⁴⁺ in the doped Ta₃N₅ would require the formation of V_{N} and/or O_{N} to compensate the imbalanced charge. Hence, Ta₃N₅ with a larger charge imbalance by doping had a higher oxygen-to-anion (O/N+O) molar ratio, which were 3.0%, 7.9%, 12.2% and 17.1% for Ta₃N₅, Ta₃N₅:Zr, Ta₃N₅:Mg and Ta₃N₅:Mg+Zr, respectively (FIG. 15). This was also in agreement with the result of the surface TaOxNy atomic ratios revealed by XPS (FIGS. 13A-C). Moreover, a narrow-linewidth EPR signal was detected at g-value of 1.982 in Ta₃N₅:Mg and Ta₃N₅:Mg+Zr (FIG. 16), which was most likely assigned to VN^{●●}. The deviation observed for the g-value from that expected for V_{N}^{●●} (˜2.0023 (ge)) would be due to some orbital mixing with the empty states of nearby Ta⁵⁺, in line with a similar EPR signal with g-value of 1.960 found for V_{O}^{●} in ZnO. Note that V^{Ø} was not considered because it does not contribute to charge compensation. This was a specific observation for Mg-doped samples, probably because the substitution of Ta⁵⁺ by Mg²⁺ produced a larger positive charge deficiency than that by Zr⁴⁺ or Ta³⁺ to be compensated. Note that V_{N}^{●●●} and V_{N}^{●}, EPR-silent species, must exist in the undoped Ta₃N₅ to compensate the imbalanced charge arising from Ta³⁺, and they may also exist with different abundances in the doped Ta₃N₅. To summarize, pristine Ta₃N₅ was comparatively rich of Ta³⁺ and V_{N}^{●●●}/V_{N}^{●}, but was poor of O_{N}. The sample owning fewest defects was Ta₃N₅:Zr (no Ta³⁺, minor O_{N} and possibly few V_{N}^{●●●}/V_{N}^{●}), followed by Ta₃N₅:Mg+Zr (no Ta³⁺, several O_{N}, minor V_{N}^{●●} and possibly few V_{N}^{●●●}/V_{N}^{●}). Although Ta³⁺ was eliminated in Ta₃N₅:Mg, V_{N}^{●●} (directly detected) and V_{N}^{●●●}/V_{N}^{●} were majorly formed as defects in this sample, corresponding to its relatively intense background absorbance (FIG. 12).

Time-resolved absorption (TA) spectroscopic measurements were carried out using a pump-probe system equipped with Nd:YAG laser (Continuum, Surelite I; duration: 6 ns) and custom-built spectrometers. Photogenerated charge carriers were probed from visible to mid-IR region: 20000-1000 cm⁻¹ (500-10000 nm). In the visible-near IR region (20000-6000 cm⁻¹), the probe light emitted from the halogen lamp was focused on the sample and the reflected light passing through the spectrometer equipped with monochromatic gratings was finally detected by Si photodetectors. In the mid-IR region (6000-1000 cm⁻¹), the IR probe light coming from the MoSi₂ coil was focused on the sample and the IR transmitted light was then introduced to a monochromatic grating spectrometer, allowing to monitor the photocarriers at broad band probe energies (up to 10 μm, 0.12 eV). The transmitted light was then detected by mercury-cadmium-telluride (MCT) detector (Kolmar). The time resolution of the spectrometer was limited to 1 us by the response of photodetectors. The output electric signal was amplified using AC-coupled amplifier (Stanford Research Systems (SR560), bandwidth: 1 MHz), which can measure responses from one microsecond-millisecond timescales. Laser pulses (470 nm, 1 or 0.1 mJ pulse⁻¹) were used to excite the charge carriers on undoped and doped Ta₃N₅, with and without Pt cocatalysts.

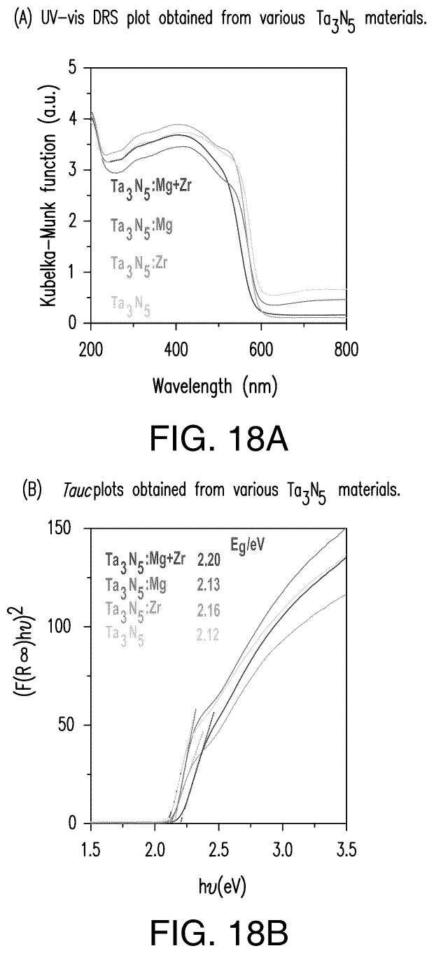

The result of defect species study described above was further supported by the transient absorption (TA) kinetic profiles of charge carriers probed at 2000 cm⁻¹ (5000 nm) on a microsecond timescale (FIG. 17), reflecting the intra-band transition of free and/or shallowly trapped electrons in/near the conduction band of different Ta₃N₅. Undoped Ta₃N₅ exhibited the lowest TA intensity and fast decay due to rapid trapping of electrons at deep states, most likely arising from Ta³⁺ (FIG. 14), the well-known recombination center in Ta₃N₅. Ta₃N₅:Zr with fewest defect species exhibited significantly higher TA intensity at 2000 cm⁻¹ (5000 nm) with slower decay than Ta₃N₅:Mg that had more V_{N}. However, defining the functionality for each individual type of V_{N} (V_{N}^{●●} and V_{N}^{●●●}/V_{N}^{●}) remains difficult due to the complex transformation from each other upon photoexcitation. It is notable that Mg—Zr co-doping (Ta₃N₅:Mg+Zr) can further increase the population of surviving electrons (FIG. 17), most likely arising from the larger number of O_{N} (FIG. 15) that was widely recognized as shallow traps in Ta₃N₅ and can elongate the lifetime of electrons via trapping and de-trapping process. As a result of the compositional alteration (different dopants and defect species), a slight bandgap enlargement caused by doping was found (FIGS. 18A-B).

TABLE 1
Chemical compositions of different Ta₃N₅ materials
determined by ICP-AES and combustion analysis.

| | Weight ratio (wt. %)/Atomic ratio (at. %) | | | | |
|---|---|---|---|---|---|
| Sample | Ta^{a} | Mg^{a} | Zr^{a} | N^{b} | O^{b} |
| Ta₃N₅:Mg + Zr | 80.4/30.4 | 1.2/3.4 | 5.1/3.8 | 10.6/51.7 | 2.5/10.7 |
| Ta₃N₅:Mg | 85.8/34.1 | 1.1/3.2 | 0.0/0.0 | 10.7/55.0 | 1.7/7.6 |
| Ta₃N₅:Zr | 82.0/32.7 | 0.0/0.0 | 5.1/4.0 | 11.3/58.3 | 1.1/5.0 |
| Ta₃N₅ | 88.0/36.9 | 0.0/0.0 | 0.0/0.0 | 11.3/61.2 | 0.4/1.9 |

^{a}Measured by ICP-AES; ICPS-8100, Shimadzu
^{b}Measured by the N—O combustion analyzer

TABLE 2
Areas of the deconvoluted Ta 4ƒ XPS peaks at the specific binding energies.

| | Ta species | | | | | | | | |
|---|---|---|---|---|---|---|---|---|---|
| | N—Ta—N (Ta₃N₅) | | | | | O—Ta—N (TaOₓN_{y}) | | | |
| | | | Atomic | Ta³⁺ | | Atomic | | | Atomic |
| | Peak area at B.E.= | | ratio | Peak area at B.E.= | | ratio | Peak area at B.E.= | | ratio |
| Sample | 24.5 eV | 26.4 eV | (at. %) | 23.6 eV | 25.5 eV | (at. %) | 26.0 eV | 27.9 eV | (at. %) |
| Ta₃N₅:Mg + Zr | 23667.5 | 17750.6 | 95.2 | 0.0 | 0.0 | 0 | 1184.5 | 888.4 | 4.8 |
| Ta₃N₅:Mg | 29085.6 | 21814.2 | 96.4 | 0.0 | 0.0 | 0 | 1100.1 | 825.1 | 3.6 |
| Ta₃N₅:Zr | 29213.1 | 21909.8 | 96.9 | 0.0 | 0.0 | 0 | 933.9 | 700.4 | 3.1 |
| Ta₃N₅ | 33350.6 | 25012.9 | 85.5 | 4981.2 | 3735.9 | 12.8 | 668.4 | 501.3 | 1.7 |

### Example 2

Ta Nanopowder Precursor. NaCl-contained Ta nanopowder (NaCl/Ta), the precursor for Ta₃N₅ synthesis, was used and available from Global Advanced Metals USA, Inc. The NaCl/Ta material was mainly characterized with micron-sized NaCl crystals surrounded by aggregated spherical Ta nanoparticles (FIG. 2). The molar ratio of NaCl/Ta was determined to be 4.5 according to the inductively coupled plasma-atomic emission spectroscopy (ICP-AES; ICPS-8100, Shimadzu) analysis.

Synthesis of Doped Ta₃N₅. 0.67 g of NaCl/Ta was well mixed with 92.1 μL of aqueous MgCl₂ solution (2 M; Sigma-Aldrich BioUltra), 92.1 μL aqueous ZrOCl₂ solution (2 M; Fujifilm Wako Pure Chemical Industries, Ltd.) and 300 μL of ultrapure H₂O in an agate mortar. The feed molar ratio of Ta/Mg/Zr was about 7.5/1/1. After desiccating the mixture by mild heating at 60° C. and grinding for around 20 min, the solid was carefully loaded into an alumina crucible, and further heated to 900° C. with a ramping rate of 10° C./min and held at 900° C. for 3 h under a gaseous NH3 flow of 200 mL/min. After natural cooling to room temperature, the obtained sample was washed with hot water (70° C.), and then dried at 40° C. for 6 h under vacuum conditions. Ta₃N₅:Mg+Zr (feed molar ratio of Ta/Mg/Zr=7.5/1/1) was obtained. The material Ta₃N₅:Mg+Zr is the Doped Ta₃N₅.

Synthesis of Cocatalyst Doped Ta₃N₅. Pt as the hydrogen evolution cocatalyst was loaded onto the surface of the Doped Ta₃N₅ by a stepwise process utilizing an impregnation-H₂ thermal reduction (IMP) method followed by an in-situ photodeposition (PD) method. For the IMP method, Doped Ta₃N₅ was first well-dispersed in an aqueous solution containing the required amount of H₂PtCl₆ as the Pt precursor by sonication for 1 min. The slurry was further heated by hot water vapor under manual stirring using a glass rod until it turned dry. After heating the powder at 250° C. for 1 h under a H₂/N₂ gaseous flow (H₂: 20 mL/min; N₂: 200 mL/min), the sample PtIMP/Doped Ta₃N₅ was obtained. Samples were prepared with Pt IMP loadings of 0 wt %, 0.05 wt %, 0.1 wt %, and 0.2 wt %. Following, a required amount of H₂PtCl₆ was added to an aqueous reaction solution containing PtIMP/Doped Ta₃N₅ photocatalyst. Pt was loaded onto PtIMP/Doped Ta₃N₅ in-situ under photocatalytic reaction conditions (PD method). The Pt loading by PD method was 0.9 wt. %. The resulting catalysts were the Doped Ta₃N₅ loaded with a total of 0.9 wt % Pt (0% IMP/0.9% PD); 0.95 wt % Pt (0.05% IMP/0.9% PD); 1.0 wt % Pt (0.1% IMP/0.9% PD); and 1.1 wt % Pt (0.2% IMP/0.9% PD). Similar to above, as comparison examples, Doped Ta₃N₅ with 1.0 wt. % Pt by the IMP method and Doped Ta₃N₅ with 1.0 wt. % Pt by the PD method were also prepared.

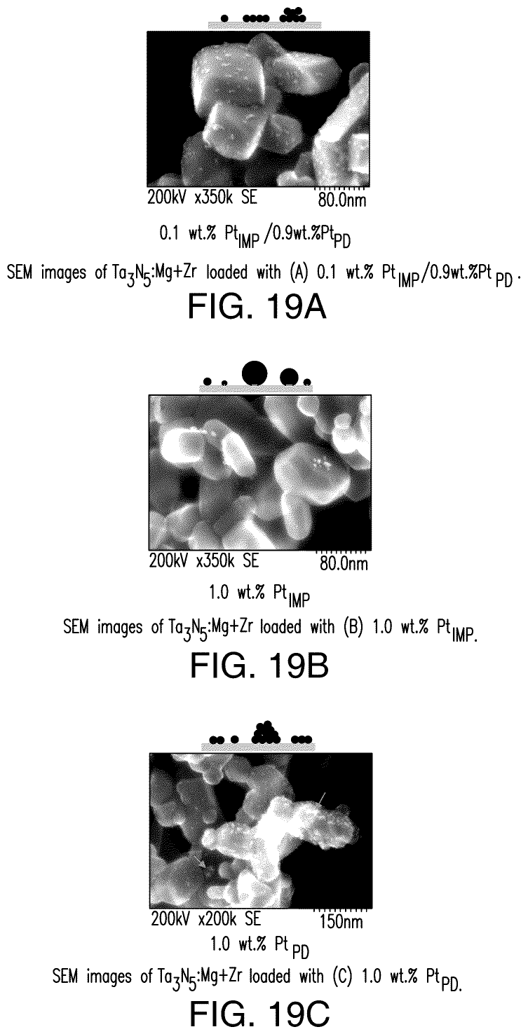

Examination of the catalyst samples found the stepwise process produced more evenly distributed Pt on the surface of the catalyst. Particularly, deposition of 1.0 wt. % Pt by a stepwise method (0.1% IMP/0.9% PD) provided a more even distribution of Pt nanoparticles with small sizes (around 2 mm-5 nm) and less aggregation (FIGS. 19A-C).

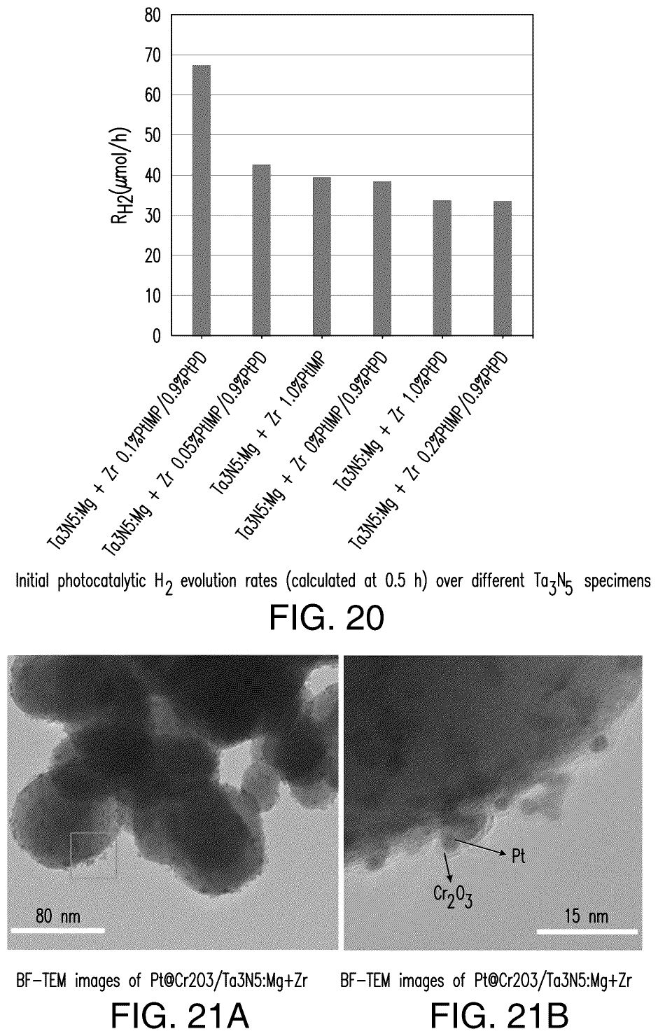

Photocatalytic H₂ Evolution Reaction. All photocatalytic reactions were carried out at 12° C. implemented by a cooling water system in a Pyrex top-illuminated reaction vessel connected to a closed gas-circulation system. The Pt Cocatalyst Doped Ta₃N₅ were each well-dispersed in 150 mL aqueous methanol solution (130 mL H₂O+20 mL MeOH) with a pH value of around 7. After completely degassing the reaction slurry by evacuation, a required amount of argon gas was introduced to create a background pressure of ca. 7 kPa, and the reactant solution was irradiated with a 300 W xenon lamp equipped with a cold mirror and a cut-off filter (L42, λ≥420 nm). The evolved gas products were analyzed by an integrated online thermal-conductivity-detector gas chromatography system consisting of a GC-8A chromatograph (Shimadzu) equipped with molecular sieve 5 Å columns, with argon as the carrier gas. The rate of hydrogen produced was found to be Ta₃N₅:Mg+Zr 0.1% PtIMP/0.9% PtPD>>Ta₃N₅:Mg+Zr 0.05% PtIMP/0.9% PtPD>Ta₃N₅:Mg+Zr 1.0% PtIMP≈Ta₃N₅:Mg+Zr 0% PtIMP/0.9% PtPD>Ta₃N₅:Mg+Zr 1.0% PtPD≈Ta₃N₅:Mg+Zr 0.2% PtIMP/0.9% PtPD (FIG. 20).

### Example 3

Ta Nanopowder Precursor. NaCl-contained Ta nanopowder (NaCl/Ta), the precursor for Ta₃N₅ synthesis, was used and available from Global Advanced Metals USA, Inc. The NaCl/Ta material was mainly characterized with micron-sized NaCl crystals surrounded by aggregated spherical Ta nanoparticles (FIG. 2). The molar ratio of NaCl/Ta was determined to be 4.5 according to the inductively coupled plasma-atomic emission spectroscopy (ICP-AES; ICPS-8100, Shimadzu) analysis.

Synthesis of Doped Ta₃N₅. 0.67 g of NaCl/Ta was well mixed with 92.1 μL of aqueous MgCl2 solution (2 M; Sigma-Aldrich BioUltra), 92.1 μL aqueous ZrOCl2 solution (2 M; Fujifilm Wako Pure Chemical Industries, Ltd.) and 300 μL of ultrapure H₂O in an agate mortar. The feed molar ratio of Ta/Mg/Zr was about 7.5/1/1. After desiccating the mixture by mild heating at 60° C. and grinding for around 20 min, the solid was carefully loaded into an alumina crucible, and further heated to 900° C. with a ramping rate of 10° C./min and held at 900° C. for 3 h under a gaseous NH₃ flow of 200 mL/min. After natural cooling to room temperature, the obtained sample was washed with hot water (70° C.), and then dried at 40° C. for 6 h under vacuum conditions. Ta₃N₅:Mg+Zr (feed molar ratio of Ta/Mg/Zr=7.5/1/1) was obtained. The material Ta₃N₅:Mg+Zr is the Doped Ta₃N₅.

Synthesis of Cocatalyst Doped Ta₃N₅. Pt as the hydrogen evolution cocatalyst was loaded onto the surface of the Doped Ta₃N₅ by a stepwise process utilizing an impregnation-H₂ thermal reduction (IMP) method followed by an in-situ photodeposition (PD) method. For the IMP method, Doped Ta₃N₅ was first well-dispersed in an aqueous solution containing the required amount of H₂PtCl₆ as the Pt precursor by sonication for 1 min. The slurry was further heated by hot water vapor under manual stirring using a glass rod until it turned dry. After heating the powder at 250° C. for 1 h under a H₂/N₂ gaseous flow (H₂: 20 mL/min; N₂: 200 mL/min), the sample PtIMP/Doped Ta₃N₅ was obtained with a Pt IMP loading of 0.1 wt %. Following, a required amount of H₂PtCl₆ was added to an aqueous reaction solution containing PtIMP/Doped Ta₃N₅ photocatalyst. Pt was loaded onto PtIMP/Doped Ta₃N₅ in-situ under photocatalytic reaction conditions. The Pt loading by PD method was 0.9 wt. %. The resulting catalysts was the Doped Ta₃N₅ loaded with a total of 1.0 wt % Pt; 0.1 wt % Pt by IMP and 0.9 wt % Pt by PD and is designated as Pt/Ta₃N₅:Mg+Zr. This catalyst was the same as in Example 1.

Synthesis of Coated Cocatalyst Doped Ta₃N₅. Cr₂O₃ was coated onto the surface of the Pt/Ta₃N₅:Mg+Zr using a photo-reduction method. K₂CrO₄ was dissolved in an aqueous methanol solution followed by the addition of the Cocatalyst Doped Ta₃N₅. Irradiating the solution reduced the K₂CrO₄(Cr6+) to Cr₂O₃ (Cr3+) forming a Pt/Cr₂O₃ core-shell nanostructure of a uniform thin layer of Cr₂O₃ on the Pt. The resulting Coated Cocatalyst Doped Ta₃N₅ is labeled as Cr₂O₃/Pt/Ta₃N₅:Mg+Zr or Pt@Cr₂O₃/Ta₃N₅:Mg+Zr.

The formation of a Pt/Cr₂O₃ core-shell nanostructure was demonstrated by the TEM analysis (FIGS. 21A-B). The actual concentrations of Pt and Cr in the Cr₂O₃/Pt/Ta₃N₅:Mg+Zr were 0.97 wt. % and 0.37 wt. %, respectively. It is noted that the Cr shell was evidently composed of Cr(III)O1.5-m(OH)2m·xH₂O, 18 based on the identification of both Cr₂O₃ and Cr(OH)₃ species with binding energies of 576.1 (this peak could be further fitted using a multiplet) and 577.3 eV, respectively. However, it is labeled as Cr₂O₃ for the sake of simplicity.

Photocatalytic H₂ Evolution Reaction. The hydrogen evolution activity of Cr₂O₃/Pt/Ta₃N₅:Mg+Zr was compared against the uncoated Pt/Ta₃N₅:Mg+Zr. Note, the only difference between these two materials is the addition or absence of the Cr₂O₃ layer. Photocatalytic reactions were carried out at 12° C. implemented by a cooling water system in a Pyrex top-illuminated reaction vessel connected to a closed gas-circulation system. The Cr₂O₃/Pt/Ta₃N₅:Mg+Zr and Pt/Ta₃N₅:Mg+Zr were each well-dispersed in 150 mL aqueous methanol solution (130 mL H₂O+20 mL MeOH) with a pH value of around 7. After completely degassing the reaction slurry by evacuation, a required amount of argon gas was introduced to create a background pressure of ca. 7 kPa, and the reactant solution was irradiated with a 300 W xenon lamp equipped with a cold mirror and a cut-off filter (L42, λ≥420 nm). The evolved gas products were analyzed by an integrated online thermal-conductivity-detector gas chromatography system consisting of a GC-8A chromatograph (Shimadzu) equipped with molecular sieve 5 Å columns, with argon as the carrier gas.

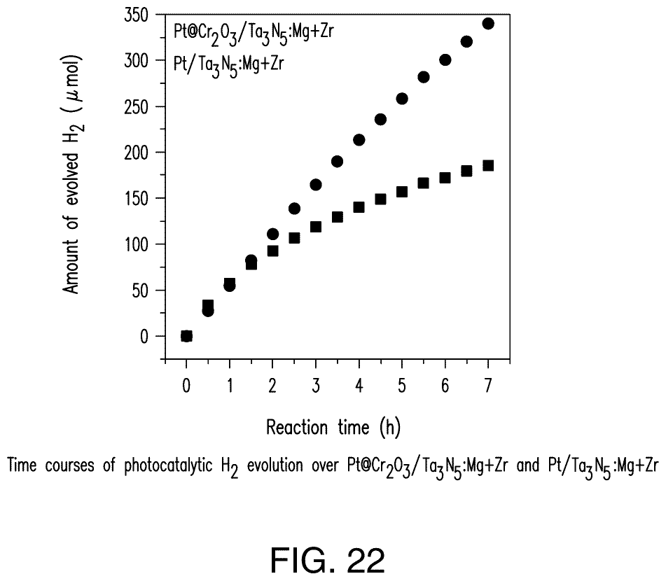

The Cr₂O₃/Pt/Ta₃N₅:Mg+Zr catalyst demonstrated a consistent high level of hydrogen production compared against the Pt/Ta₃N₅:Mg+Zr (FIG. 22). The continuous higher hydrogen production of Cr₂O₃/Pt/Ta₃N₅:Mg+Zr indicates the core-shell nanostructure likely inhibits the deactivation of the photocatalytic water reduction from methanol oxidative intermediates.

Apparent quantum yield (AQY) measurement. Under the H₂ Evolution Reaction conditions, the AQY for H₂ evolution was measured. The light source was a 300 W Xe lamp (MAX-303 Compact Xenon Light Source, Asahi Spectra) with bandpass filters of 420, 460, 500, 540, 580, 620, and 660 nm central wavelengths (full-width at half-maximum=15 nm), respectively. The number of incident photons was measured using a LS-100 grating spectroradiometer (EKO Instruments Co., Ltd.), and the AQY was 31 calculated according to the equation below.

AQY (%)=[2×n_{H}_{₂}]/nₚₕₒₜₒₙ×100

where n_{H}_{₂} and nₚₕₒₜₒₙ indicate the numbers of evolved H₂ molecules and incident photons, respectively. The coefficient of 2 denotes that two photons are used to form one H₂ molecule.

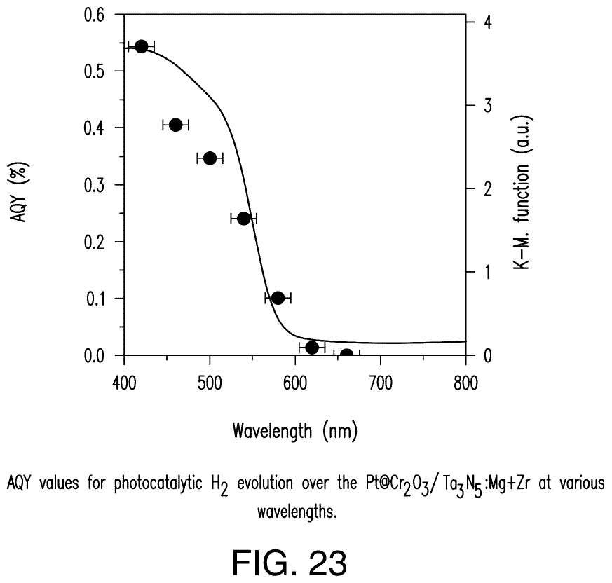

The AQY for photocatalytic H₂ production over Pt@Cr₂O₃/Ta₃N₅:Mg+Zr was measured as a function of the irradiation wavelength (FIG. 23). The AQY value at 420 nm was 0.54%, which is significantly higher than that reported for the reproducible photocatalytic H₂ evolution reaction (HER) over Ta₃N₅ in the literature, which was ≤ 0.1%.

The present invention includes the following aspects/embodiments/features in any order and/or in any combination:
1. The present invention relates to single crystalline nanoparticles that are tantalum nitride doped with at least one metal.
2. The single crystalline nanoparticles or method or other embodiment of any preceding or following embodiment/feature/aspect, wherein the tantalum nitride is co-doped with two metals.
3. The single crystalline nanoparticles or method or other embodiment of any preceding or following embodiment/feature/aspect, wherein the two metals are Zr and Mg.
4. The single crystalline nanoparticles or method or other embodiment of any preceding or following embodiment/feature/aspect, wherein the tantalum nitride is Ta₃N₅.
5. The single crystalline nanoparticles or method or other embodiment of any preceding or following embodiment/feature/aspect, wherein the at least one metal resides as a cation in a crystal lattice of the tantalum nitride.
6. The single crystalline nanoparticles or method or other embodiment of any preceding or following embodiment/feature/aspect, wherein the single crystalline nanoparticles are Ta₃N₅:Mg+Zr, or Ta₃N₅:Mg, or Ta₃N₅:Zr or any combination thereof.
7. The single crystalline nanoparticles or method or other embodiment of any preceding or following embodiment/feature/aspect, wherein the single crystalline nanoparticles exhibit single-phase X-ray diffraction (XRD) patterns associated with anosovite-type Ta₃N₅.
8. The single crystalline nanoparticles or method or other embodiment of any preceding or following embodiment/feature/aspect, wherein EPR-active Ta⁴⁺ is not present at −173.15° C.
9. The single crystalline nanoparticles or method or other embodiment of any preceding or following embodiment/feature/aspect, wherein the single crystalline nanoparticles are monodispersed nanorod particles.
10. The single crystalline nanoparticles or method or other embodiment of any preceding or following embodiment/feature/aspect, wherein the monodispersed nanorod particles have an average length of from 50 nm to 500 nm.
11. The single crystalline nanoparticles or method or other embodiment of any preceding or following embodiment/feature/aspect, wherein all Mg²⁺ and Zr⁴⁺ cations reside in the crystal lattice of Ta₃N₅.
12. The single crystalline nanoparticles or method or other embodiment of any preceding or following embodiment/feature/aspect, wherein Mg-to-cation (Mg/(Ta+Mg+Zr)) and Zr-to-cation (Zr/(Ta+Mg+Zr)) ratios reached as high as 9.0 mol. % and 10.2 mol. %, respectively.
13. The single crystalline nanoparticles or method or other embodiment of any preceding or following embodiment/feature/aspect, wherein minor segregated phases of MgO, Zr₂ON₂, NaTaO₃ and ZrO₂ are not present.
14. The single crystalline nanoparticles or method or other embodiment of any preceding or following embodiment/feature/aspect, wherein an atomic ratio of surface Ta in the form of Ta₃N₅ (N—Ta—N) is over 90 at %.
15. The single crystalline nanoparticles or method or other embodiment of any preceding or following embodiment/feature/aspect, wherein an atomic ratio of surface Ta in the form of Ta₃N₅ (N—Ta—N) is 91 at % to 98 at %.
16. The single crystalline nanoparticles or method or other embodiment of any preceding or following embodiment/feature/aspect, wherein an atomic ratio of surface Ta in the form of Ta³⁺ is below 1 at %.
17. The single crystalline nanoparticles or method or other embodiment of any preceding or following embodiment/feature/aspect, wherein an atomic ratio of surface Ta in the form of Ta³⁺ is undetectable or below 0.001 at %.
18. The single crystalline nanoparticles or method or other embodiment of any preceding or following embodiment/feature/aspect, wherein an atomic ratio of surface Ta in the form of TaOₓN_{y} (O—Ta—N) is 2 at % or more.
19. The single crystalline nanoparticles or method or other embodiment of any preceding or following embodiment/feature/aspect, wherein an atomic ratio of surface Ta in the form of TaOₓN_{y} (O—Ta—N) is 2 at % to 5 at %.
20. The single crystalline nanoparticles or method or other embodiment of any preceding or following embodiment/feature/aspect, wherein said monodispersed nanorods have an aspect ratio (length/width) of at least 1.2.
21. The single crystalline nanoparticles or method or other embodiment of any preceding or following embodiment/feature/aspect, wherein the single crystalline nanoparticles are monodispersed.
22. The single crystalline nanoparticles or method or other embodiment of any preceding or following embodiment/feature/aspect, wherein the single crystalline nanoparticles have a charge imbalance resulting in an oxygen-to-anion (O/N+O) molar ratio of 4.0% or higher.
23. The single crystalline nanoparticles or method or other embodiment of any preceding or following embodiment/feature/aspect, wherein the single crystalline nanoparticles have a charge imbalance resulting in an oxygen-to-anion (O/N+O) molar ratio of 5.0% to about 18%.
24. The single crystalline nanoparticles or method or other embodiment of any preceding or following embodiment/feature/aspect, wherein the single crystalline nanoparticles have a transient absorption (TA) kinetic profile of charged particles that is higher than undoped Ta₃N₅.
25. The single crystalline nanoparticles or method or other embodiment of any preceding or following embodiment/feature/aspect, wherein the single crystalline nanoparticles have an evolved H₂ with a rate (R_{H2}) of at least 2 μmol/h where such rates are based on a Pt loading of 0.9 wt % Pt based on the total weight of the nanoparticles and the Pt loading are Pt particles having an average size of from about 2 to about 5 nm.
26. The single crystalline nanoparticles or method or other embodiment of any preceding or following embodiment/feature/aspect, wherein the single crystalline nanoparticles have an evolved H₂ with a rate (R_{H2}) of from 10 μmol/h to 70 μmol/h where such rates are based on a Pt loading of 0.9 wt % Pt based on the total weight of the nanoparticles and the Pt loading are Pt particles having an average size of from about 2 mm to about 5 nm.
27. The single crystalline nanoparticles or method or other embodiment of any preceding or following embodiment/feature/aspect, wherein the single crystalline nanoparticles are in the substantial or detectable absence of one or more of the following minor segregated phases: MgO, Zr₂ON₂, NaTaO₃, and/or ZrO₃.
28. The single crystalline nanoparticles or method or other embodiment of any preceding or following embodiment/feature/aspect, wherein the single crystalline nanoparticles are in the substantial or detectable absence of one or more of the following defect species: Ta³⁺ or Ta⁴⁺, or V_{N}, or O_{N}.
29. A catalyst comprising the single crystalline nanoparticles of any preceding or following embodiment/feature/aspect, wherein along or in combination with at least one co-catalyst.
30. The catalyst or method or other embodiment of any preceding or following embodiment/feature/aspect, wherein said at least one co-catalyst is present and is evenly distributed on the surface of the single crystalline nanoparticles.
31. The catalyst or method or other embodiment of any preceding or following embodiment/feature/aspect, wherein said catalyst is a photocatalyst.
32. The catalyst or method or other embodiment of any preceding or following embodiment/feature/aspect, wherein said catalyst has a solar-to-hydrogen (STH) energy conversion efficiency of over 0.015%.
33. The catalyst or method or other embodiment of any preceding or following embodiment/feature/aspect, wherein said catalyst has a solar-to-hydrogen (STH) energy conversion efficiency of from 0.015% to 0.1%.
34. The catalyst or method or other embodiment of any preceding or following embodiment/feature/aspect, wherein said catalyst has an H₂ production that is over 5 μmol/h.
35. The catalyst or method or other embodiment of any preceding or following embodiment/feature/aspect, wherein said catalyst has an H₂ production that is from 5 μmol/h to 13 μmol/h.
36. The catalyst or method or other embodiment of any preceding or following embodiment/feature/aspect, wherein the catalyst has a higher photocatalytic water reduction activity than pristine Ta₃N₅ under visible-light irradiation.
37. The catalyst or method or other embodiment of any preceding or following embodiment/feature/aspect, wherein the catalyst has an apparent quantum yield (AQY) at 420 nm of over 0.15% for a photocatalytic H₂ evolution reaction (HER).
38. The catalyst or method or other embodiment of any preceding or following embodiment/feature/aspect, wherein the catalyst has an apparent quantum yield (AQY) at 420 nm of from 0.15% to 0.54% for a photocatalytic H₂ evolution reaction (HER).
39. The catalyst or method or other embodiment of any preceding or following embodiment/feature/aspect, wherein said at least one co-catalyst is present and comprises Pt.
40. A method to water split, said method comprising utilizing said catalyst of any preceding or following embodiment/feature/aspect, in a fluid or solution, such as an aqueous solution, along with an energy source.
41. The method or other embodiment of any preceding or following embodiment/feature/aspect, wherein energy source is solar energy.
42. The present invention also relates to a method to make the single crystalline nanoparticles of any preceding or following embodiment/feature/aspect, wherein said method comprising impregnating a NaCl/Ta with MgCl₂ or other first metal salt and ZrOCl₂ or other second metal salt and then conducting nitridation under a flow of gas.
43. The method or other embodiment of any preceding or following embodiment/feature/aspect, wherein said gas is NH₃.
44. The method or other embodiment of any preceding or following embodiment/feature/aspect, wherein said nitriding is conducted at a temperature of 900 deg C. or higher.
45. The method or other embodiment of any preceding or following embodiment/feature/aspect, wherein said NaCl/Ta is a NaCl-encapsulated Ta from a sodium/halide flame encapsulation method.
46. The method to make the catalyst of any preceding or following embodiment/feature/aspect, wherein said at least one co-catalyst is present and said method comprises the loading of said at least one co-catalyst onto the single crystalline nanoparticles.
47. A method or other embodiment of any preceding or following embodiment/feature/aspect, wherein said loading comprises deposition of the co-catalyst or a precursor thereof by an impregnation-reduction method followed by deposition of additional co-catalyst by in-situ photodeposition.
48. The method or other embodiment of any preceding or following embodiment/feature/aspect, wherein said loading by said impregnation-reduction method accounts for from 70% to 95% of total co-catalyst loading by wt % of co-catalyst present.
49. The method or other embodiment of any preceding or following embodiment/feature/aspect, wherein said catalyst is a heterogeneous phase in contact with the fluid or the solution.

The present invention can include any combination of these various features or embodiments above and/or below as set forth in sentences and/or paragraphs. Any combination of disclosed features herein is considered part of the present invention and no limitation is intended with respect to combinable features.

The disclosure herein refers to certain illustrated examples, it is to be understood that these examples are presented by way of example and not by way of limitation. The intent of the foregoing detailed description, although discussing exemplary examples, is to be construed to cover all modifications, alternatives, and equivalents of the examples as may fall within the spirit and scope of the invention as defined by the additional disclosure.

The entire contents of all cited references in this disclosure, to the extent that they are not inconsistent with the present disclosure, are incorporated herein by reference.

The present invention can include any combination of the various features or embodiments described above and/or in the claims below as set forth in sentences and/or paragraphs. Any combination of disclosed features herein is considered part of the present invention and no limitation is intended with respect to combinable features.

Other embodiments of the present invention will be apparent to those skilled in the art from consideration of the present specification and practice of the present invention disclosed herein. It is intended that the present specification and examples be considered as exemplary only with a true scope and spirit of the invention being indicated by the following claims and equivalents thereof.

1. Single crystalline nanoparticles that are tantalum nitride doped with at least one metal.

2. The single crystalline nanoparticles of claim 1, wherein the tantalum nitride is co-doped with two metals.

3. The single crystalline nanoparticles of claim 2, wherein the two metals are Zr and Mg.

4. The single crystalline nanoparticles of claim 1, wherein the tantalum nitride is Ta₃N₅.

5. The single crystalline nanoparticles of claim 1, wherein the at least one metal resides as a cation in a crystal lattice of the tantalum nitride.

6. The single crystalline nanoparticles of claim 1, wherein the single crystalline nanoparticles are Ta₃N₅:Mg+Zr, or Ta₃N₅:Mg, or Ta₃N₅:Zr or any combination thereof.

7. The single crystalline nanoparticles of claim 6, wherein the single crystalline nanoparticles exhibit single-phase X-ray diffraction (XRD) patterns associated with anosovite-type Ta3N5.

8. The single crystalline nanoparticles of claim 6, wherein EPR-active Ta⁴⁺ is not present at −173.15° C.

9. The single crystalline nanoparticles of claim 6, wherein the single crystalline nanoparticles are monodispersed nanorod particles.

10. The single crystalline nanoparticles of claim 9, wherein the monodispersed nanorod particles have an average length of from 50 nm to 500 nm.

11. The single crystalline nanoparticles of claim 6, wherein all Mg²⁺ and Zr⁴⁺ cations reside in the crystal lattice of Ta3N5.

12. The single crystalline nanoparticles of claim 6, wherein Mg-to-cation (Mg/(Ta+Mg+Zr)) and Zr-to-cation (Zr/(Ta+Mg+Zr)) ratios reached as high as 9.0 mol. % and 10.2 mol. %, respectively.

13. The single crystalline nanoparticles of claim 6, wherein minor segregated phases of MgO, Zr2ON2, NaTaO3 and ZrO2 are not present.

14. The single crystalline nanoparticles of claim 6, wherein an atomic ratio of surface Ta in the form of Ta3N5 (N—Ta—N) is over 90 at %.

15. The single crystalline nanoparticles of claim 6, wherein an atomic ratio of surface Ta in the form of Ta3N5 (N—Ta—N) is 91 at % to 98 at %.

16. The single crystalline nanoparticles of claim 6, wherein an atomic ratio of surface Ta in the form of Ta³⁺ is below 1 at %.

17. The single crystalline nanoparticles of claim 6, wherein an atomic ratio of surface Ta in the form of Ta³⁺ is undetectable or below 0.001 at %.

18. The single crystalline nanoparticles of claim 6, wherein an atomic ratio of surface Ta in the form of TaOxNy (O—Ta—N) is 2 at % or more.

19. The single crystalline nanoparticles of claim 6, wherein an atomic ratio of surface Ta in the form of TaOxNy (O—Ta—N) is 2 at % to 5 at %.

20. The single crystalline nanoparticles of claim 9, wherein said monodispersed nanorods have an aspect ratio (length/width) of at least 1.2.

21. The single crystalline nanoparticles of claim 6, wherein the single crystalline nanoparticles are monodispersed.

22. The single crystalline nanoparticles of claim 6, wherein the single crystalline nanoparticles have a charge imbalance resulting in an oxygen-to-anion (O/N+O) molar ratio of 4.0% or higher.

23. The single crystalline nanoparticles of claim 6, wherein the single crystalline nanoparticles have a charge imbalance resulting in an oxygen-to-anion (O/N+O) molar ratio of 5.0% to about 18%.

24. The single crystalline nanoparticles of claim 6, wherein the single crystalline nanoparticles have a transient absorption (TA) kinetic profile of charged particles that is higher than undoped Ta₃N₅.

25. The single crystalline nanoparticles of claim 6, wherein the single crystalline nanoparticles have an evolved H₂ with a rate (R_{H2}) of at least 2 μmol/h where such rates are based on a Pt loading of 0.9 wt % Pt based on the total weight of the nanoparticles and the Pt loading are Pt particles having an average size of from about 2 mm to about 5 nm.

26. The single crystalline nanoparticles of claim 6, wherein the single crystalline nanoparticles have an evolved H₂ with a rate (R_{H2}) of from 10 μmol/h to 70 μmol/h where such rates are based on a Pt loading of 0.9 wt % Pt based on the total weight of the nanoparticles and the Pt loading are Pt particles having an average size of from about 2 mm to about 5 nm.

27. The single crystalline nanoparticles of claim 6, wherein the single crystalline nanoparticles are in the substantial or detectable absence of one or more of the following minor segregated phases: MgO, Zr₂ON₂, NaTaO₃, and/or ZrO₃.

28. The single crystalline nanoparticles of claim 6, wherein the single crystalline nanoparticles are in the substantial or detectable absence of one or more of the following defect species: Ta³⁺ or Ta⁴⁺, or V_{N}, or O_{N}.

29. A catalyst comprising the single crystalline nanoparticles of claim 6 along or in combination with at least one co-catalyst.

30. The catalyst of claim 29, wherein said at least one co-catalyst is present and is evenly distributed on the surface of the single crystalline nanoparticles.

31. The catalyst of claim 29, wherein said catalyst is a photocatalyst.

32. The catalyst of claim 29, wherein said catalyst has a solar-to-hydrogen (STH) energy conversion efficiency of over 0.015%.

33. The catalyst of claim 29, wherein said catalyst has a solar-to-hydrogen (STH) energy conversion efficiency of from 0.015% to 0.1%.

34. The catalyst of claim 29, wherein said catalyst has an H₂ production that is over 5 μmol/h.

35. The catalyst of claim 29, wherein said catalyst has an H₂ production that is from 5 μmol/h to 13 μmol/h.

36. The catalyst of claim 29, wherein the catalyst has a higher photocatalytic water reduction activity than pristine Ta₃N₅ under visible-light irradiation.

37. The catalyst of claim 29, wherein the catalyst has an apparent quantum yield (AQY) at 420 nm of over 0.15% for a photocatalytic H₂ evolution reaction (HER).

38. The catalyst of claim 29, wherein the catalyst has an apparent quantum yield (AQY) at 420 nm of from 0.15% to 0.54% for a photocatalytic H₂ evolution reaction (HER).

39. The catalyst of claim 29, wherein said at least one co-catalyst is present and comprises Pt.

40. A method to water split, said method comprising utilizing said catalyst of claim 29 in a fluid or solution along with an energy source.

41. The method of claim 40, wherein said catalyst is a heterogeneous phase in contact with the fluid or the solution.

42. The method of claim 40, wherein energy source is solar energy.

43. A method to make the single crystalline nanoparticles of claim 6, said method comprising impregnating a NaCl/Ta with MgCl₂ or other first metal salt and ZrOCl₂ or other second metal salt and then conducting nitridation under a flow of gas.

44. The method of claim 43, wherein said gas is NH₃.

45. The method of claim 43, wherein said nitriding is conducted at a temperature of 900 deg C. or higher.

46. The method of claim 43, wherein said NaCl/Ta is a NaCl-encapsulated Ta from a sodium/halide flame encapsulation method.

47. The method to make the catalyst of claim 29, wherein said at least one co-catalyst is present and said method comprises the loading of said at least one co-catalyst onto the single crystalline nanoparticles.

48. A method of claim 47, wherein said loading comprises deposition of the co-catalyst or a precursor thereof by an impregnation-reduction method followed by deposition of additional co-catalyst by in-situ photodeposition.

49. The method of claim 48, wherein said loading by said impregnation-reduction method accounts for from 70% to 95% of total co-catalyst loading by wt % of co-catalyst present.
